(19) United States
(12) Patent Application Publication
(10) Pub. No.: US 2020/0106023 A1
(43) Pub. Date: Apr. 2, 2020

(54) Thermally Activated Delayed Material and Organic Photoelectric Device Comprising the Same

(71) Applicant: Shanghai Tianma AM-OLED Co., Ltd., Shanghai (CN)

(72) Inventors: Lei Zhang, Shanghai (CN); Wei Gao, Shanghai (CN); Qing Zhu, Shanghai (CN); Jinghua Niu, Shanghai (CN); Gaojun Huang, Shanghai (CN)

(73) Assignee: Shanghai Tianma AM-OLED Co., Ltd., Shanghai (CN)

(21) Appl. No.: 16/409,376

(22) Filed: May 10, 2019

(30) Foreign Application Priority Data
Sep. 30, 2018 (CN) 201811160762.2

(51) Int. Cl. H01L 51/00; C07F 5/02; C09K 11/06

(52) U.S. Cl. CPC H01L 51/0071; C07F 5/027; C09K 11/06; H01L 51/5012; C09K 2211/1007; C09K 2211/1018; C09K 2211/1011; H01L 51/0072

(57) ABSTRACT

The present disclosure relates to a thermally activated delayed material and an organic photoelectric device comprising the same, and the thermally activated delayed material is a compound having the structure of formula (I). The organic photoelectric device comprises an anode, a cathode, and an organic thin film layer between the anode and the cathode; the organic thin film layer comprises a light emitting layer, and any one selected from the group consisting of a hole transporting layer, a hole injection layer, an electron blocking layer, a hole blocking layer, an electron transporting layer, an electron injection layer, and a combination of at least two thereof. The light emitting layer comprises any one or a combination of at least two of the thermally activated delayed materials, and the compound is used as any one of a dopant material, a co-doping material, or a host material.

### CROSS-REFERENCE TO RELATED APPLICATIONS

The application claims the benefit of the earlier filing date of C.N. Patent Application No. 201811160762.2, filed on Sep. 30, 2019, the contents of which are incorporated by reference herein in its entirety.

### TECHNICAL FIELD

The present disclosure relates to the technical field of organic electroluminescent materials, and in particular to a thermally activated delayed material and an organic photoelectric device comprising the same.

### BACKGROUND

According to luminescence mechanisms, there are four main materials that can be used for OLED light emitting layer: fluorescent materials, phosphorescent materials, triplet-triplet annihilation (TTA) materials, and thermally activated delayed fluorescence (TADF) materials. Wherein, the theoretical maximum internal quantum yield of the fluorescent material does not exceed 25%, the theoretical maximum internal quantum yield of the TTA material does not exceed 62.5%; and the theoretical maximum internal quantum yields of the phosphorescent material and the TADF material can reach 100%. However, the phosphorescent material is basically a heavy metal complex of Ir, Pt, Os, Re, Ru, etc., which has high production cost and is not conducive to large-scale production; and at high current density, the phosphorescent material has a serious efficiency roll-off phenomenon. In addition, the stability of phosphorescent devices is also not good.

TADF materials can simultaneously utilize 75% of triplet excitons and 25% of singlet excitons, the theoretical maximum quantum yield thereof can reach 100%, and the luminous efficiency thereof can be comparable with that of phosphorescent materials. TADF materials are mainly organic compounds, which do not need rare metal elements, have low production cost, and can be chemically modified by a variety of methods. TADF materials are new organic electroluminescent materials which are very promising. However, the TADF materials having been found are fewer and the performance thereof needs to be improved. New TADF materials that can be used for OLED devices need to be developed urgently.

Therefore, more kinds of TADF materials with higher performances need to be developed urgently.

### SUMMARY

In order to develop more kinds of TADF materials with higher performances, the first object of the present disclosure is to provide a thermally activated delayed material which is a compound having the structure of formula (I):

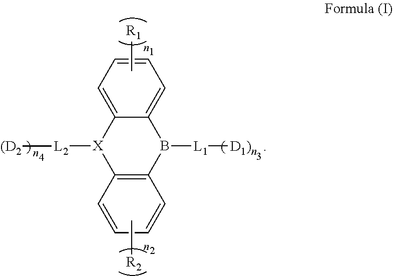

In formula (I), X is a boron atom or a nitrogen atom.

In formula (I), D₁ and D₂ are each independently any one selected from the following groups:

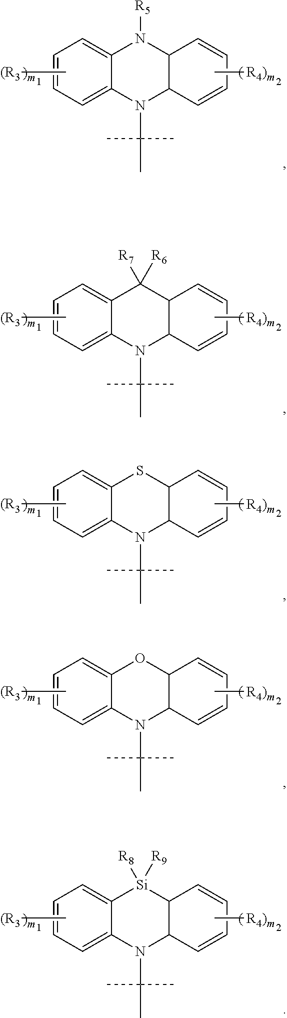

Wherein R₃, R₄, R₅, R₆, R₇, R₈ and R₉ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl.

m₁ and m₂ are each independently an integer of 0-4, for example 1, 2, 3, etc.; in the same group, the sum of m₁ and m₂ is less than or equal to 4, for example 1, 2, 3, etc.

In formula (I), R₁ and R₂ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl.

In formula (I), n₁ and n₂ are each independently an integer of 0-4, for example, 1, 2, 3, etc., and the sum of n₁ and n₂ is less than or equal to 4, for example, 1, 2, 3, etc.

In formula (I), n₃ and n₄ are each independently an integer greater than or equal to 0, for example 1, 2, 3, 5, 7, 9, 11, 15, 18, etc.

In formula (I), L₁ and L₂ are each independently any one selected from substituted or unsubstituted aromatic groups; and the number of the substituents on the aromatic group in L₁ and L₂ is represented by m₃.

The thermally activated delayed material provided by the present disclosure has a boron-containing compound group as an electron-withdrawing group, combining with a group of an acridine-based structure as an electron-donating group, so that electron clouds of the electron-withdrawing group and the electron-donating group have a suitable degree of overlap, enabling the energy level difference (ΔE_{ST}=E_{S1}−E_{T1}) between the lowest singlet state S₁ and the lowest triplet state T₁ of the thermally activated delayed material to be less than or equal to 0.30 eV, even less than or equal to 0.15 eV. Thus, the thermally activated delayed material provided by the present disclosure has a TADF material luminescence mechanism and can be used in the field of organic photoelectric devices to improve luminous efficiency.

The second object of the present disclosure is to provide an organic photoelectric device comprising an anode, a cathode, and at least one organic thin film layer between the anode and the cathode; the organic thin film layer comprises a light emitting layer, and any one selected from the group consisting of a hole transporting layer, a hole injection layer, an electron blocking layer, a hole blocking layer, an electron transporting layer, an electron injection layer, and a combination of at least two thereof.

The light emitting layer includes any one or a combination of at least two of the thermally activated delayed materials according to the first object, and the compound is used as any one of a dopant material, a co-doping material, or a host material.

### BRIEF DESCRIPTION OF THE DRAWINGS

FIG. 1 is a schematic view showing the structure of the organic photoelectric device provided by the present disclosure.

FIG. 2 is a structural view of the organic photoelectric device provided by an example of the present disclosure.

### DETAIL DESCRIPTION

To facilitate the understanding of the present disclosure, examples of the present application are listed below. It should be understood by those skilled in the art that the examples are only intended to assist in understanding the present disclosure and should not be construed as limitations to the present disclosure.

The first object of the present disclosure is to provide a thermally activated delayed material which is a compound having the structure of formula (I):

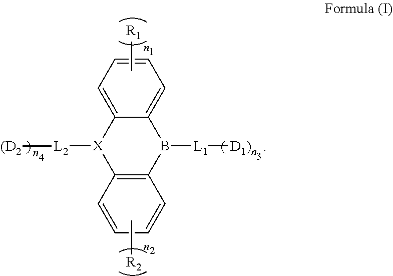

In formula (I), X is a boron atom or a nitrogen atom.

In formula (I), D₁ and D₂ are each independently any one selected from the following groups:

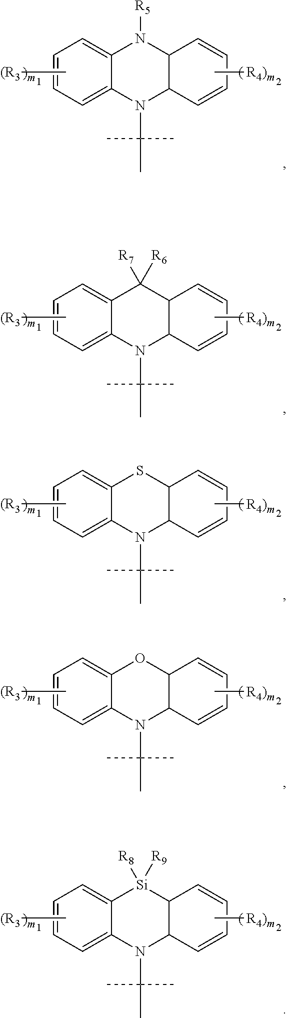

Wherein R₃, R₄, R₅, R₆, R₇, R₈ and R₉ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl.

The thermally activated delayed material provided by the present disclosure has a boron-containing compound group as an electron-withdrawing group, combining with a group of an acridine-based structure as an electron-donating group, so that electron clouds of the electron-withdrawing group and the electron-donating group have a suitable degree of overlap, enabling the energy level difference (ΔE_{ST}=E_{S1}−E_{T1}) between the lowest singlet state S₁ and the lowest triplet state T₁ of the thermally activated delayed material to be less than or equal to 0.30 eV, even less than or equal to 0.15 eV.

Wherein, m₁ and m₂ are each independently an integer of 0-4, for example 1, 2, 3, etc.; in the same group, the sum of m₁ and m₂ is less than or equal to 4, for example 1, 2, 3, etc.

In formula (I), R₁ and R₂ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl.

In formula (I), n₁ and n₂ are each independently an integer of 0-4, for example 1, 2, 3, etc., and the sum of n₁ and n₂ is less than or equal to 4, for example 1, 2, 3, etc.

In formula (I), n₃ and n₄ are each independently an integer greater than or equal to 0, for example 1, 2, 3, 5, 7, 9, 11, 15, 18, etc.

In formula (I), L₁ and L₂ are each independently any one selected from substituted or unsubstituted aromatic groups; and the number of the substituents on the aromatic group in L₁ and L₂ is represented by m₃.

ΔE_{ST} is positively correlated with the degree of overlap between HOMO and LUMO. The degree of overlap between HOMO and LUMO is reduced by introducing electron donor unit D and electron acceptor unit A and large sterically hindered building unit L, and thereby ΔE_{ST} is reduced.

In one embodiment, the sum of n₁, n₂, m₁, m₂ and m₃ is less than or equal to 4, for example 3, 2, 1, 0, etc.

In one embodiment, the sum of n₁, n₂, m₁ and m₂ is 0 or 1.

In one embodiment, the sum of n₁, n₂, m₁, m₂ and m₃ is less than or equal to 3, for example 2, 1, 0, etc.

In one embodiment, m₁=0 or m₂=0, or R₁, R₂, R₃ or R₄ are each independently any one selected from the group consisting of methyl, ethyl, phenyl and tolyl.

In one embodiment, R₅, R₆, R₇, R₈ and R₉ are each independently any one selected from the group consisting of methyl, ethyl, phenyl and tolyl.

In one embodiment, in formula (I), L₁ group is located on para position or meta position.

In one embodiment, in formula (I), D₁-L₁- group is the same as D₂-L₂- group.

When D₁-L₁- group is the same as D₂-L₂- group, firstly, the synthesis step is reduced, and therefore the synthesis is convenient; secondly, when the two are the same, the electron donating ability is enhanced, and the HOMO level of the whole molecule is shifted upward, so that the energy gap of the molecular is reduced, which facilitates the material to emit deep blue light.

In one embodiment, in formula (I), both n₁ and n₂ are 0, and D₁-L₁- group and D₂-L₂-group are the same.

In one embodiment, L₁ and L₂ are each independently selected from any one of the following groups, or any one of the following groups substituted with a substituent:

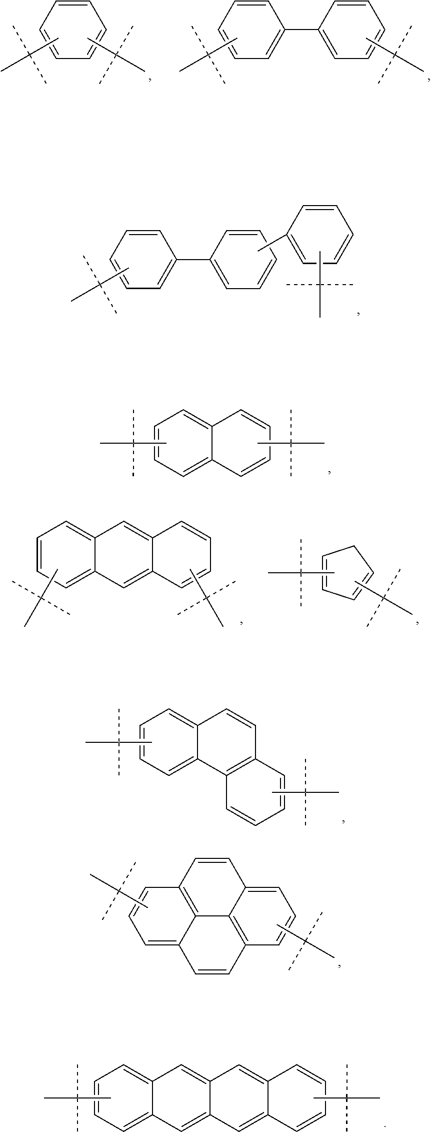

In one embodiment, L₁ and L₂ are each independently selected from any one of the following groups, or any one of the following groups substituted with a substituent:

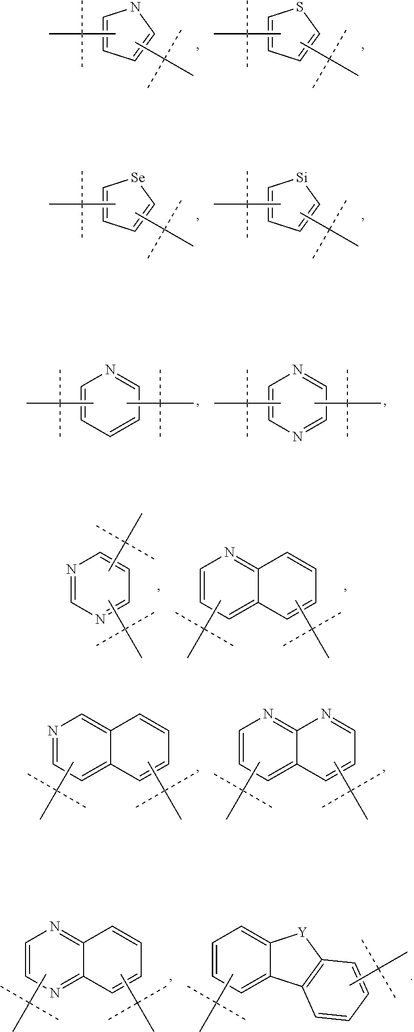

In one embodiment, the energy level difference (ΔE_{ST}=E_{S1}−E_{T1}) between the lowest singlet state S₁ and the lowest triplet state T₁ of the thermally activated delayed material is less than or equal to 0.30 eV, for example 0.29 eV, 0.28 eV, 0.27 eV, 0.26 eV, 0.25 eV, 0.24 eV, 0.23 eV, 0.22 eV, 0.21 eV, 0.20 eV, 0.19 eV, 0.18 eV, 0.16 eV, 0.14 eV, 0.13 eV, 0.12 eV, 0.11 eV, 0.10 eV, 0.09 eV, 0.08 eV, 0.07 eV, 0.06 eV, 0.05 eV, 0.04 eV, 0.03 eV, 0.02 eV, 0.01 eV, etc.

In one embodiment, for the thermally activated delayed material, ΔE_{ST}≤0.15 eV, for example 0.14 eV, 0.13 eV, 0.12 eV, 0.11 eV, 0.10 eV, 0.09 eV, 0.08 eV, 0.07 eV, 0.06 eV, 0.05 eV, 0.04 eV, 0.03 eV, 0.02 eV, 0.01 eV, etc.

In one embodiment, the thermally activated delayed material comprises any one selected from the group consisting of the following compounds, and a combination of at least two thereof:

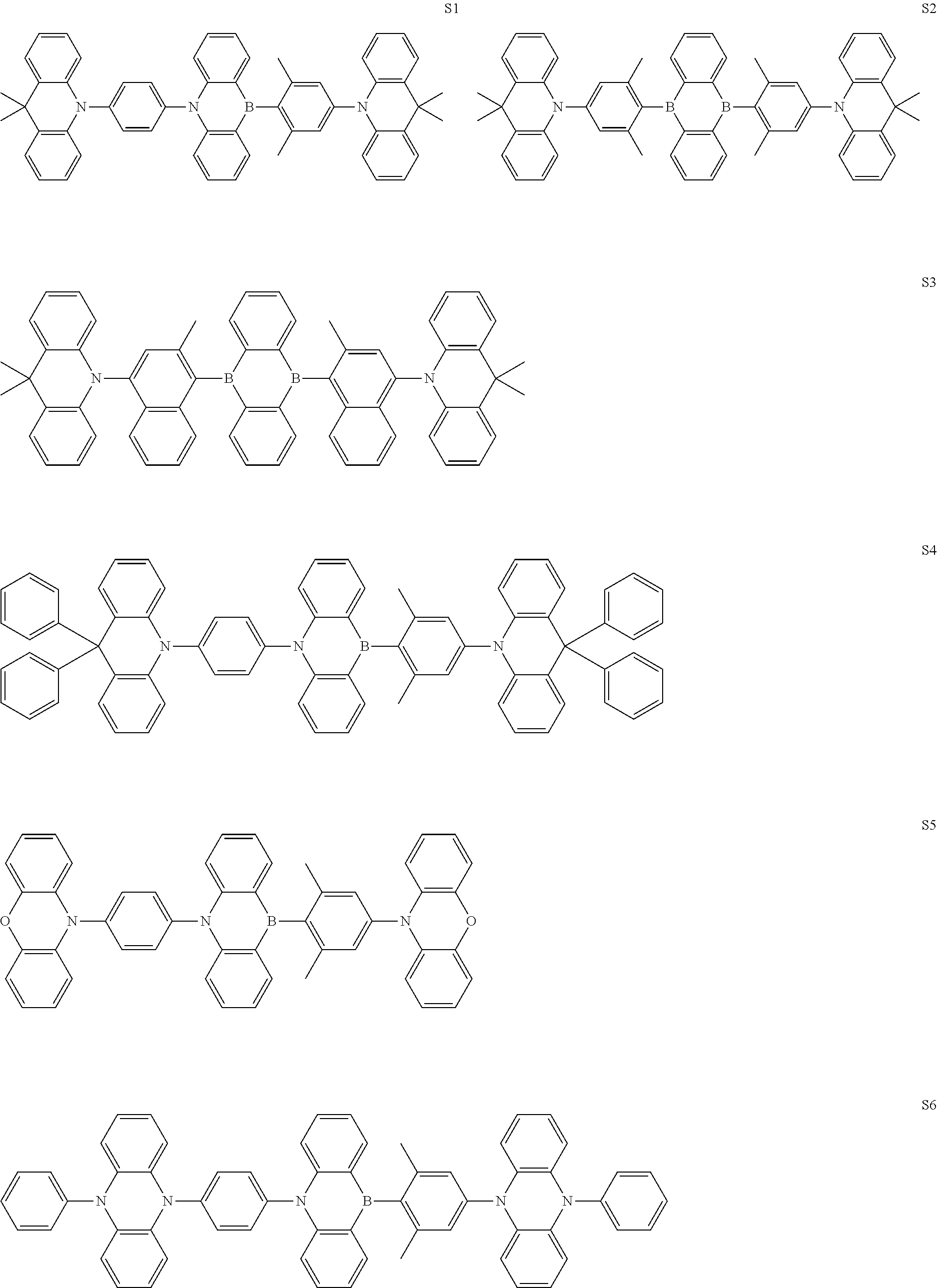

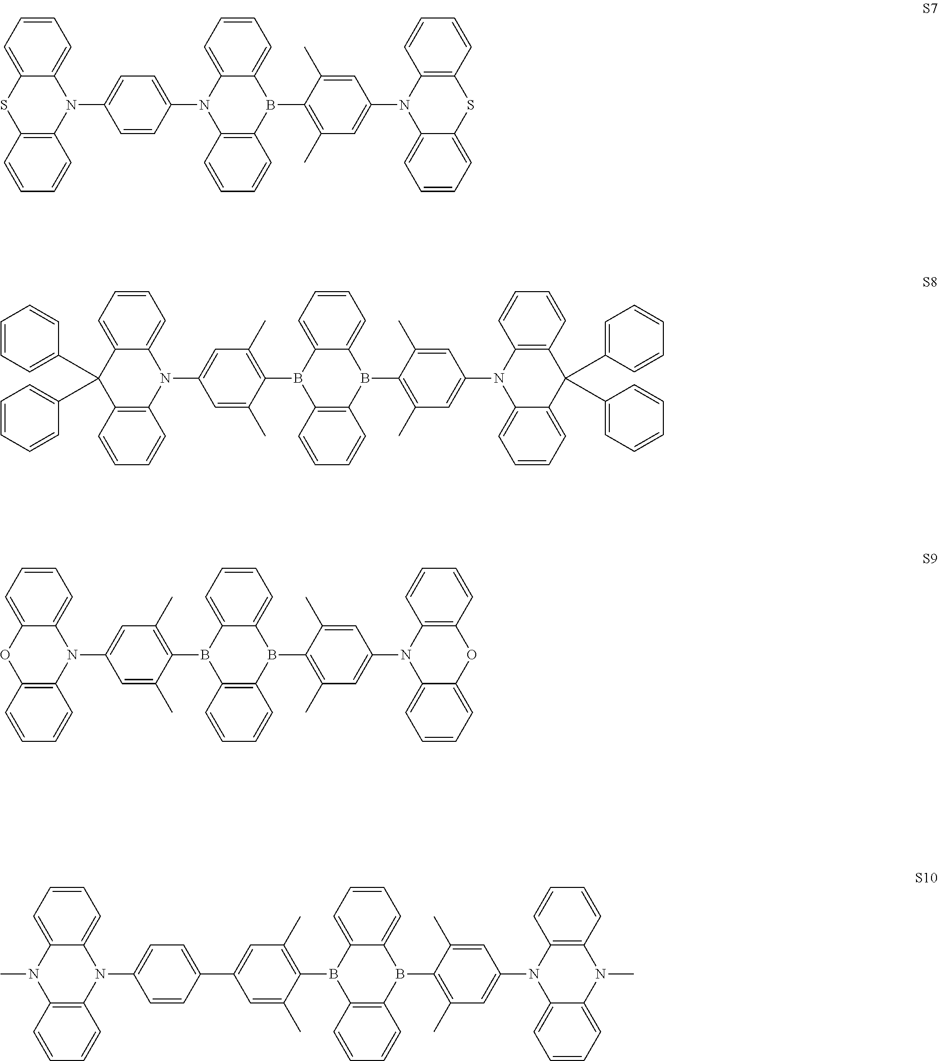

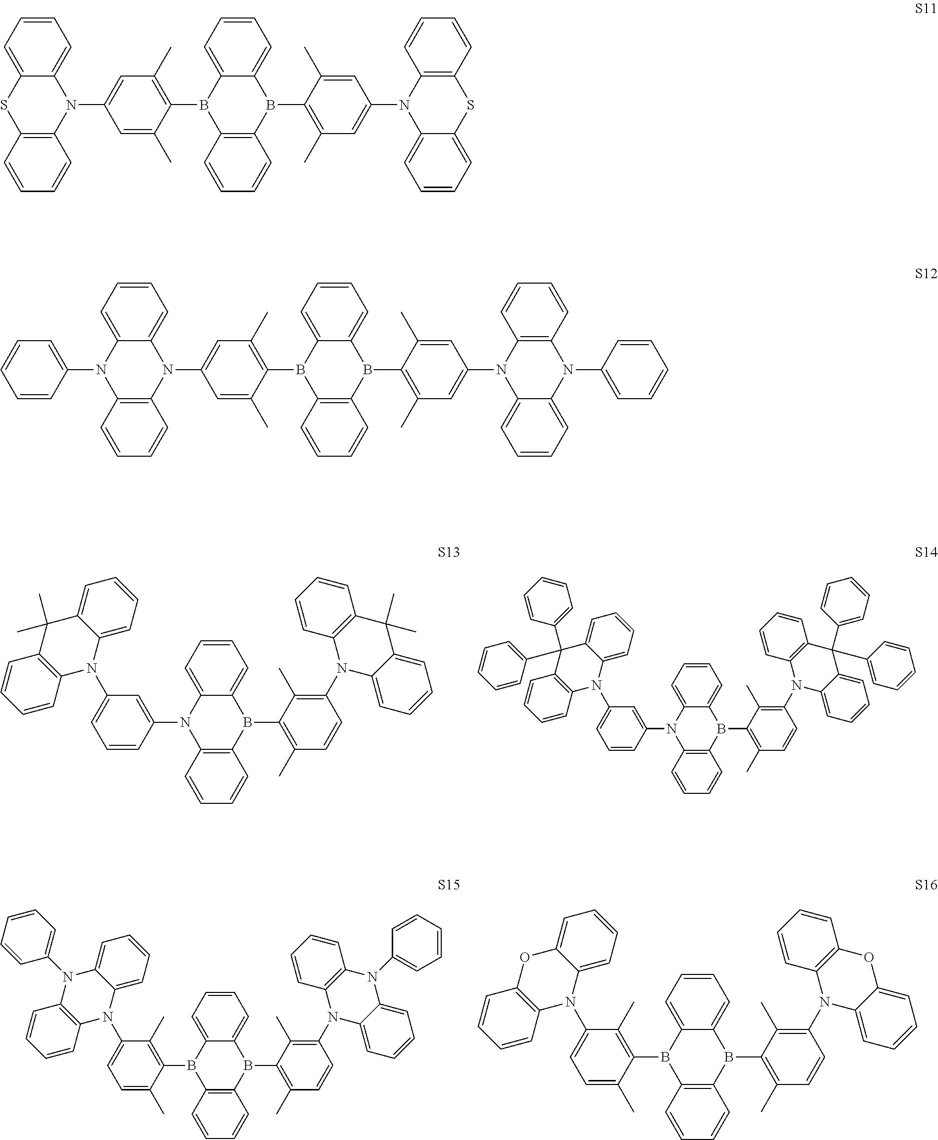

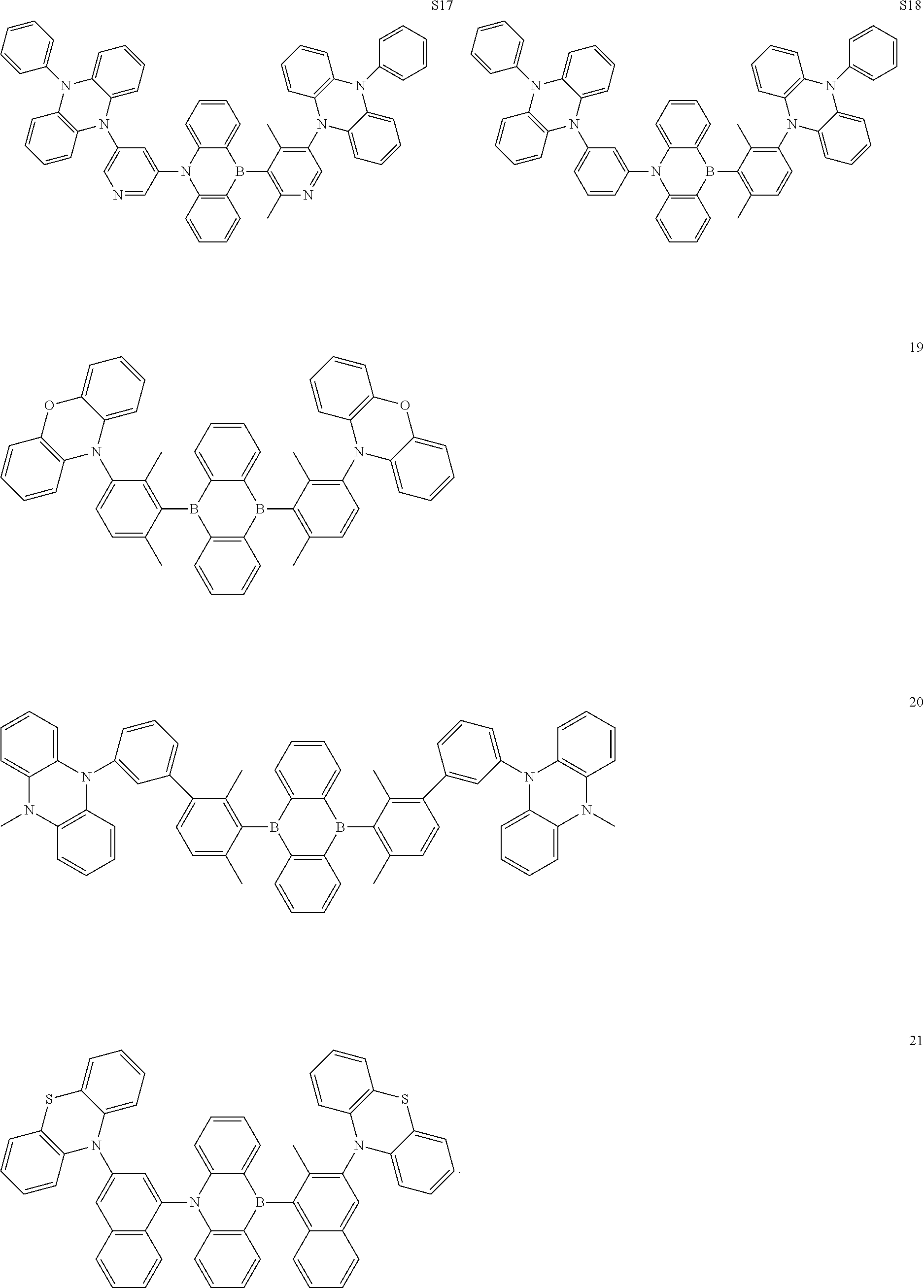

In one embodiment, the thermally activated delayed material comprises any one selected from the group consisting of the following compounds, and a combination of at least two thereof:

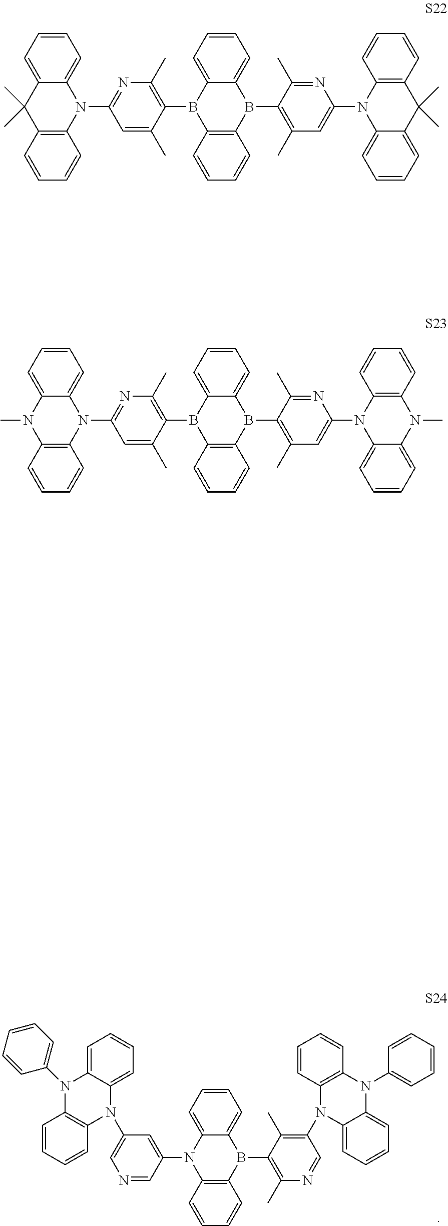

In one embodiment, the thermally activated delayed material comprises any one selected from the group consisting of the following compounds, and a combination of at least two thereof:

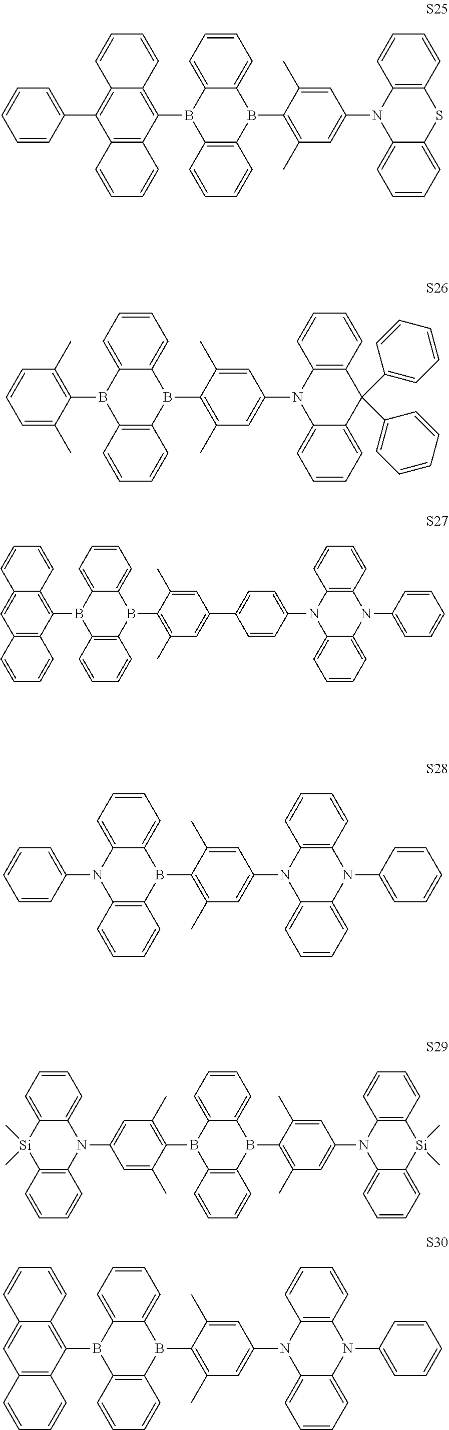

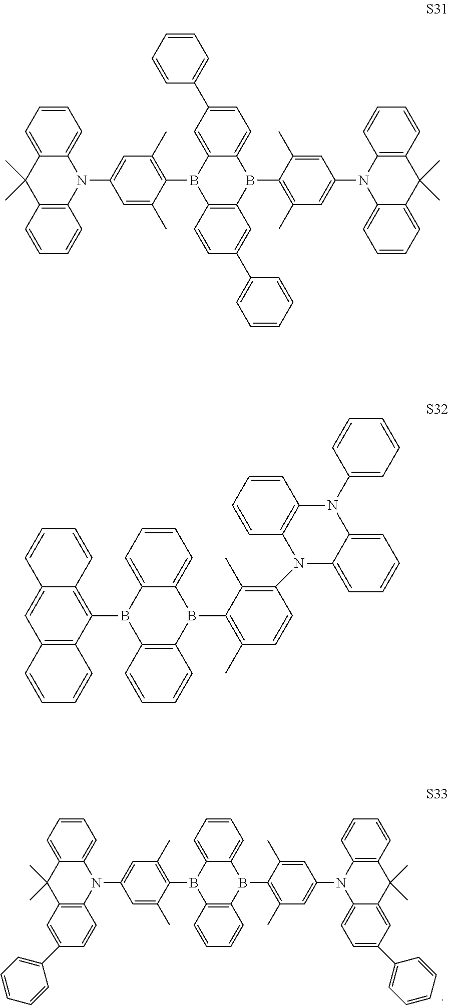

The second object of the present disclosure is to provide an organic photoelectric device comprising an anode, a cathode, and at least one organic thin film layer between the anode and the cathode; the organic thin film layer comprises a light emitting layer, and any one selected from the group consisting of a hole transporting layer, a hole injection layer, an electron blocking layer, a hole blocking layer, an electron transporting layer, an electron injection layer, and a combination of at least two thereof.

The light emitting layer comprises any one or a combination of at least two of the thermally activated delayed materials according to the first object, and the compound is used as any one of a dopant material, a co-doping material, or a host material.

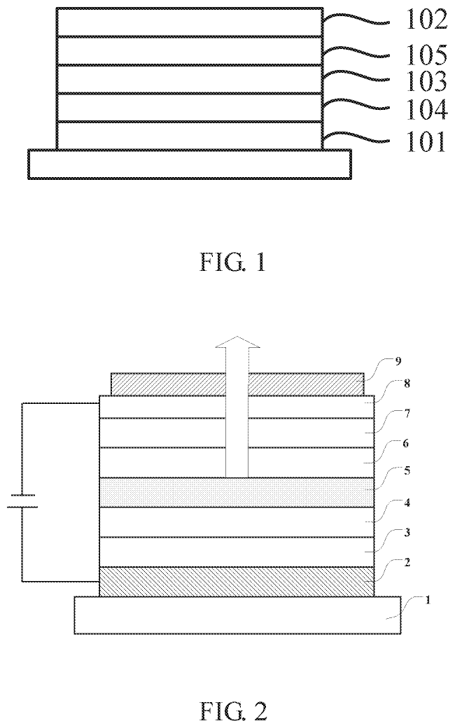

Referring to FIG. 1, the organic photoelectric device comprises an anode 101 and a cathode 102, a light emitting layer 103 disposed between the anode 101 and the cathode 102, and any one or a combination of at least two of a hole transporting layer (HTL), a hole injection layer (HIL), an electron blocking layer (EBL), a hole blocking layer (HBL), an electron transporting layer (ETL) and an electron injection layer (EIL) is/are disposed on both sides of the light emitting layer 103.

Since the thermally activated delayed material provided by the present disclosure as a luminescent material (Dopant) has ΔEₛₜ less than or equal to 0.30 eV, or even less than or equal to 0.15 eV, the reverse intersystem crossing is more easy to occur, and the long-lived triplet excitons are easily up-converted into singlet excitons, which radiate in the form of light and attenuate to the ground state S0, resulting in high photoluminescence quantum yield PLQY, and thereby, the roll-off effect can be effectively reduced and the device has good luminescence performances and the material can be used as a dopant material, a co-doping material, or a host material of the light emitting layer in organic photoelectric devices.

In one embodiment, the cathode is covered with a capping layer (CPL) which has a refractive index of 1.85-2.05.

The reason for providing the capping layer lies in that: since the refractive index of the capping layer is larger than that of the organic light emitting layer material, according to the law of refraction, the addition of the capping layer helps to enhance the emission of light in the front view direction, enhance the luminous intensity and efficiency, and even improve the life of the device.

In one embodiment, the light emitting layer is made of the thermally activated delayed material according to the first object of the present disclosure and a host material.

In one embodiment, the thermally activated delayed material is used as a guest material for the light emitting layer, and the difference between the HOMO of the host material and the HOMO of the guest material is less than 0.6 eV, for example 0.59 eV, 0.58 eV, 0.57 eV, 0.56 eV, 0.55 eV, 0.54 eV, 0.53 eV, 0.52 eV, 0.51 eV, 0.50 eV, 0.49 eV, 0.48 eV, 0.47 eV, 0.46 eV, 0.45 eV, 0.44 eV, 0.43 eV, 0.42 eV, 0.41 eV, 0.40 eV, 0.39 eV, 0.38 eV, 0.37 eV, 0.36 eV, 0.35 eV, 0.34 eV, 0.33 eV, 0.32 eV, 0.31 eV, 0.30 eV, 0.29 eV, 0.28 eV, 0.27 eV, 0.26 eV, 0.25 eV, 0.24 eV, 0.23 eV, 0.22 eV, 0.21 eV, 0.20 eV, 0.19 eV, 0.18 eV, 0.16 eV, 0.14 eV, 0.13 eV, 0.12 eV, 0.11 eV, 0.10 eV, 0.09 eV, 0.08 eV, 0.07 eV, 0.06 eV, 0.05 eV, 0.04 eV, 0.03 eV, 0.02 eV, 0.01 eV, etc. Or the difference between the LUMO of the host material and the LUMO of the guest material is less than 0.6 eV, for example 0.59 eV, 0.58 eV, 0.57 eV, 0.56 eV, 0.55 eV, 0.54 eV, 0.53 eV, 0.52 eV, 0.51 eV, 0.50 eV, 0.49 eV, 0.48 eV, 0.47 eV, 0.46 eV, 0.45 eV, 0.44 eV, 0.43 eV, 0.42 eV, 0.41 eV, 0.40 eV, 0.39 eV, 0.38 eV, 0.37 eV, 0.36 eV, 0.35 eV, 0.34 eV, 0.33 eV, 0.32 eV, 0.31 eV, 0.30 eV, 0.29 eV, 0.28 eV, 0.27 eV, 0.26 eV, 0.25 eV, 0.24 eV, 0.23 eV, 0.22 eV, 0.21 eV, 0.20 eV, 0.19 eV, 0.18 eV, 0.16 eV, 0.14 eV, 0.13 eV, 0.12 eV, 0.11 eV, 0.10 eV, 0.09 eV, 0.08 eV, 0.07 eV, 0.06 eV, 0.05 eV, 0.04 eV, 0.03 eV, 0.02 eV, 0.01 eV, etc.

In one embodiment, the thermally activated delayed material is used as a guest material for the light emitting layer, and the host material is any one selected from the group consisting of 2,8-bis(diphenylphosphinyl)dibenzothiophene, 4,4′-bis(9-carbazole)biphenyl, 3,3′-bis(N-carbazolyl)-1,1′-biphenyl, 2,8-bis(diphenylphosphinoxy)dibenzofuran, bis (4-(9H-carbazolyl-9-yl)phenyl)diphenylsilane, 9-(4-tert-butylphenyl)-3,6-bis(triphenylsilyl)-9h-carbazole, bis(2-diphenylphosphine oxide)diphenylether, 1,3-bis[3,5-di(pyridin-3-yl)phenyl]benzene, 4,6-bis(3,5-di (3-pyridin)ylphenyl)-2-methylpyrimidine, 9-(3-(9H-carbazolyl-9-yl)phenyl)-9H-carbazole-3-cyano, 9-phenyl-9-[4-(triphenylsilyl)phenyl]-9H-fluorene, 1,3,5-tris(1-phenyl-1H-benzimidazol-2-yl)benzene, diphenyl [4-(triphenylsilyl)phenyl]phosphine oxide, 4,4′,4″-tris(carbazol-9-yl)triphenylamine, 2,6-dicarbazole-1,5-pyridine, polyvinylcarbazole, polyfluorene, and a combination of at least two thereof, but is not limited to the above host materials.

In one embodiment, the thermally activated delayed material can also serve as a host material for the light emitting layer. When the material is used as a host material for the light emitting layer, the dopant material is selected from a fluorescent material such as BczVBi, coumarin-6, DCJTB, and can also be selected from a phosphorescent material or a TADF dopant luminescent material, but not limited to the above materials.

In one embodiment, the light emitting layer comprises the thermally activated delayed material according to the first object, and the hole injection material, the hole transporting material, and the electron blocking material are each independently any one selected from the group consisting of N,N′-diphenyl-N,N′-(1-naphthyl)-1,1′-biphenyl-4,4′-diamine, 4,4′,4″-tris(carbazol-9-yl)triphenylamine, 1,3-dicarbazol-9-yl benzene, 4,4′-bis(9-carbazole)biphenyl, 3,3′-bis(N-carbazolyl)-1,1′-biphenyl, 2,3,6,7,10,11-hexacyano-1,4,5,8,9,12-hexaazabenzophenanthrene, 4,4′-cyclohexyldi[N,N-di(4-methylphenyl)aniline, N,N′-diphenyl-N,N′-(1-naphthyl)-1,1′-biphenyl-4,4′-diamine, N,N′-bis(naphthalen-2-yl)-N,N′-bis(phenyl)biphenyl-4,4′-diamine, poly(3,4-ethylenedioxythiophene)-polystyrene sulfonic acid, polyvinylcarbazole, 9-phenyl-3,9-bicarbazole, molybdenum trioxide, and a combination of at least two thereof.

The hole blocking material, the electron transporting material, and the electron injection material are each independently any one selected from the group consisting of 2,8-bis(diphenylphosphinyl)dibenzothiophene, TSPO1, TPBi, 2,8-bis(diphenylphosphinoxy)dibenzofuran, bis(2-diphenylphosphine oxide)diphenylether, lithium fluoride, 4,6-bis(3,5-bis(3-pyridin)ylphenyl)-2-methylpyrimidine, 4,7-diphenyl-1,10-phenanthroline, 1,3,5-tris[(3-pyridyl)-3-phenyl]benzene, tris[2,4,6-trimethyl-3-(3-pyridyl)phenyl]borane, 1,3-bis(3,5-dipyridin-3-ylphenyl)benzene, 1,3-bis[3,5-bis(pyridin-3-yl)phenyl]benzene, 2,4,6-tris(biphenyl-3-yl)-1,3,5-triazine, diphenyl bis[4-(pyridin-3-yl)phenyl]silane, cesium carbonate, bis(2-methyl-8-hydroxyquinoline-N1,O8)-(1,1′-biphenyl-4-hydroxy)aluminum, 8-hydroxyquinoline-lithium, tris(8-hydroxyquinoline)aluminum, and a combination of at least two thereof.

The anode material may be a metal such as copper, gold, silver, iron, chromium, nickel, manganese, palladium, platinum, etc.; a metal oxide such as indium oxide, zinc oxide, indium tin oxide (ITO), indium zinc oxide (IZO), etc.; an alloy; or a conductive polymer such as polyaniline, polypyrrole, poly(3-methylthiophene), etc. In addition to the above materials and combinations thereof which contribute to hole injection, other known materials suitable for the anode may also be used.

The cathode material may be a metal such as aluminum, magnesium, silver, indium, tin, titanium, etc.; an alloy such as Mg/Ag; or a composite of a metal and an inorganic compound, such as a multilayer metal material—LiF/Al, LiO₂/Al, BaF₂/Al, etc. In addition to the above materials and combinations thereof which contribute to electron injection, other known materials suitable for the cathode may also be used.

The substrate may be a rigid substrate such as borosilicate glass, float soda lime glass, high refractive index glass, stainless steel, or may be a flexible substrate such as polyimide (PI) plastic substrate, polyethylene terephthalate (PET) plastic substrate, polyethylene naphthalate (PEN) plastic substrate, polyether sulfone resin substrate (PES), polycarbonate plastic substrate (PC), ultra-thin flexibility glass substrate, metal foil substrate.

The organic photoelectric device of the present disclosure can be prepared by a vacuum evaporation method.

The compound having the structure of formula (I) provided by the present disclosure can be synthesized by the existing technologies, and an exemplary synthetic route is as follow:

The synthetic route for a compound

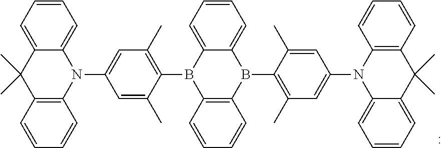

Step 1,

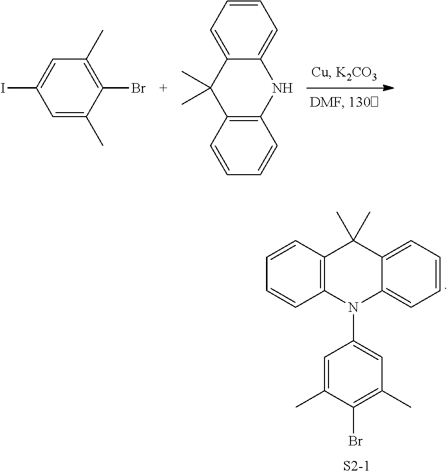

2-bromo-5-iodo-1,3-dimethylbenzene (10 mmol), 9,9-dimethylacridine (10 mmol), Cu (20 mmol), K₂CO₃ (20 mmol) and N,N-dimethylformamide (20 ml) were mixed under a nitrogen atmosphere to form a solution. The above mixed solution was vacuumed three times with nitrogen gas, and heated and stirred at 130° C. for 24 h. The reaction mixture was filtered with diatomite and washed with dichloromethane (20 ml). The solvent was evaporated under reduced pressure and the resultant was purified by column chromatography (hexane/dichloromethane: 10:1), and then a white solid 9-(4-bromo-3,5-dimethylphenyl)-dimethyl acridine S2-1 was obtained.

Step 2,

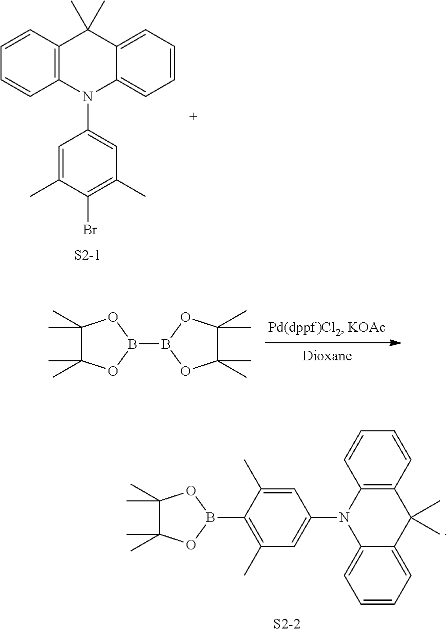

The product of the previous step 9-(4-bromo-3,5-dimethylphenyl)-dimethyl acridine S2-1 (10 mmol), bis(pinacolato)diboron (20 mmol), (1,1′-bis(diphenylphosphino)ferrocene)palladium(II)dichloride (0.3 mmol) and potassium acetate (45 mmol) were separately added into a 250 ml three-necked flask, and the mixture was vacuumed three times with nitrogen gas, and 100 mL of tetrahydrofuran was added by a syringe. The mixture was stirred at a certain speed, and the resulting mixed solution reactant was heated with reflux at a reaction temperature of 80° C. for 5 h. After the reaction was completed, the mixture was cooled to room temperature and water (100 ml) was added. Then the mixture was extracted with ethyl ether and the obtained organic phase was dried with anhydrous sodium sulfate. The solvent was distilled off and the resultant was purified by column chromatography, and then a product 9-(4-borate-3,5-dimethylphenyl)-dimethyl acridine S2-2 was obtained.

Step 3,

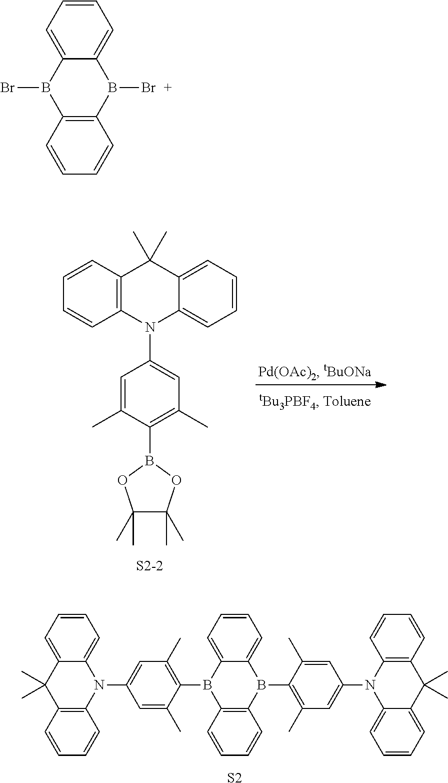

In a 250 ml three-necked flask under a nitrogen atmosphere, 9,10-dibromo-9,10-diboroanthracene (10 mmol), the product of the previous step 9-(4-borate-3,5-dimethylphenyl)-dimethyl acridine S2-2 (20 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on silica gel column to give a compound S2.

Elemental analysis for the structure of the S2 compound (molecular formula C₅₈H₅₂B₂N₂): Theoretical value: C, 87.22; H, 6.56; B, 2.71; N, 3.51. Measured Value: C, 87.22; H, 6.57; B, 2.72; N, 3.49. The ESI-MS (m/z) (M+) was obtained by liquid chromatography-mass spectrometry: the theoretical value was 798.43, and the measured value was 798.50.

The synthetic route for a compound

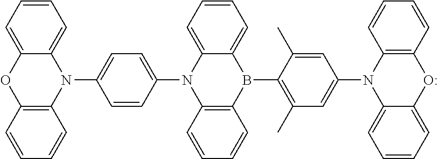

Step 1,

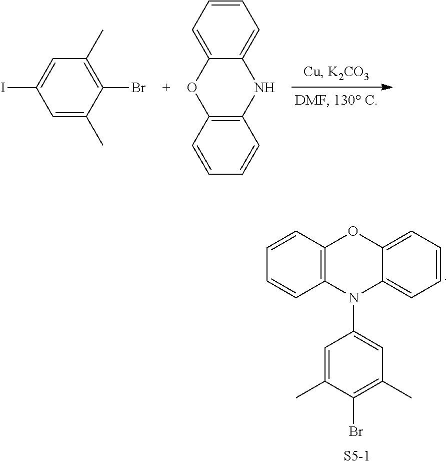

2-bromo-5-iodo-1,3-dimethylbenzene (10 mmol), phenoxazine (10 mmol), Cu (20 mmol), K₂CO₃ (20 mmol) and N,N-dimethylformamide (20 ml) were mixed under a nitrogen atmosphere to form a solution. The above mixed solution was vacuumed three times with nitrogen gas, and heated and stirred at 130° C. for 24 h. The reaction mixture was filtered with diatomite and washed with dichloromethane (20 ml). The solvent was evaporated under reduced pressure and the resultant was purified by column chromatography (hexane/dichloromethane: 10:1), and then a white solid 10-(4-bromo-3,5-dimethylphenyl)-phenoxazine S5-1 was obtained.

Step 2,

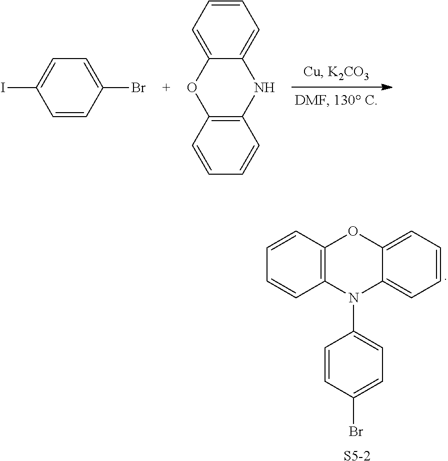 [SMILES: Brc1ccc(I)cc1 ; c1ccc2c(c1)Nc1ccccc1O2 ; Brc1ccc(N2c3ccccc3Oc3ccccc32)cc1 ; "S5-2"]

2-bromo-5-iodo-1,3-dimethylbenzene (10 mmol), phenoxazine (10 mmol), Cu (20 mmol), K₂CO₃ (20 mmol) and N,N-dimethylformamide (20 ml) were mixed under a nitrogen atmosphere to form a solution. The above mixed solution was vacuumed three times with nitrogen gas, and heated and stirred at 130° C. for 24 h. The reaction mixture was filtered with diatomite and washed with dichloromethane (20 ml). The solvent was evaporated under reduced pressure and the resultant was purified by column chromatography (hexane/dichloromethane (10:1)), and then a white solid 10-(4-bromophenyl)-phenoxazine S5-2 was obtained.

Step 3,

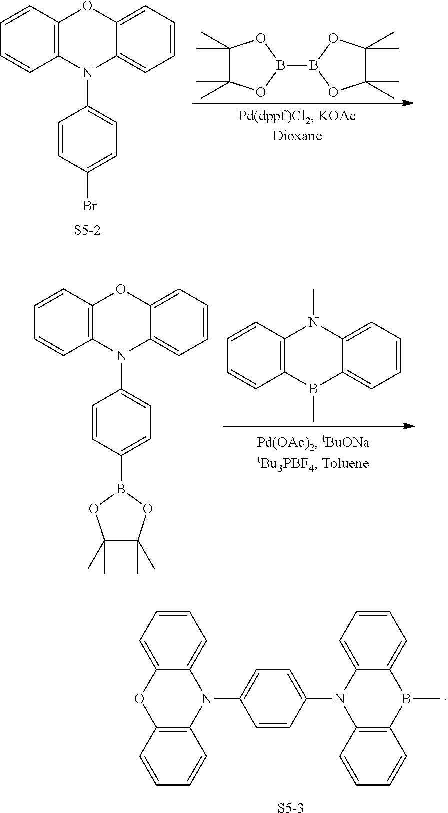

The product of the previous step 10-(4-bromophenyl)-phenoxazine (10 mmol) S5-2, bis(pinacolato)diboron (20 mmol), (1,1′-bis(diphenylphosphino)ferrocene)palladium(II)dichloride (0.3 mmol) and potassium acetate (45 mmol) were separately added into a 250 ml three-necked flask, and the mixture was vacuumed three times with nitrogen gas, and 100 mL of tetrahydrofuran was added by a syringe. The mixture was stirred at a certain speed, and the resulting mixed solution reactant was heated with reflux at a reaction temperature of 80° C. for 5 h. After the reaction was completed, the mixture was cooled to room temperature and 100 ml of water was added. Then the mixture was extracted with ethyl ether and the obtained organic phase was dried with anhydrous sodium sulfate. The solvent was distilled off and the resultant was purified by column chromatography, and then a product 9-(4-borate-3,5-dimethylphenyl)-phenoxazine was obtained.

In a 250 ml three-necked flask under a nitrogen atmosphere 5,10-dimethyl-5-nitrogen-10-boroanthracene (10 mmol), 9-(4-borate-3,5-dimethylphenyl)-phenoxazine (10 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on silica gel column to give an intermediate product S5-3.

Step 4,

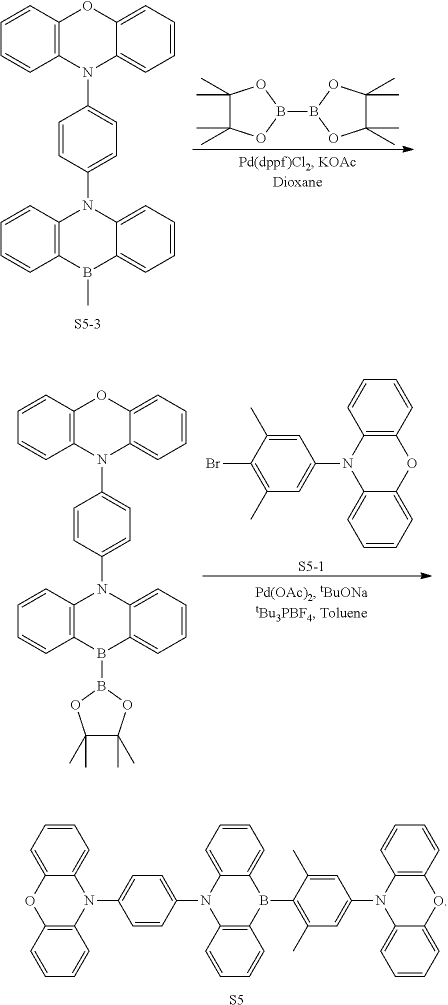

The intermediate product S5-3 (10 mmol), bis(pinacolato)diboron (20 mmol), (1,1′-bis(diphenylphosphino)ferrocene)palladium(II)dichloride (0.3 mmol) and potassium acetate (45 mmol) were separately added into a 250 ml three-necked flask, and the mixture was vacuumed three times with nitrogen gas, and 100 mL of tetrahydrofuran was added by a syringe. The mixture was stirred at a certain speed, and the resulting mixed solution reactant was heated with reflux at a reaction temperature of 80° C. for 5 h. After the reaction was completed, the mixture was cooled to room temperature and 100 ml of water was added. Then the mixture was extracted with ethyl ether and the obtained organic phase was dried with anhydrous sodium sulfate. The solvent was distilled off and the resultant was purified by column chromatography, and then a borate product of S5-3 was obtained.

In a 250 ml three-necked flask under a nitrogen atmosphere, the borate product of S5-3 (10 mmol), the product S5-1 obtained in step 1 (10 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on a silica gel column to give a final product S5.

Elemental analysis for the structure of the S5 compound (molecular formula C₅₀H₃₆BN₃O₂): Theoretical value: C, 83.22; H, 5.03; B, 1.50; N, 5.82; O, 4.43. Measured Value: C, 83.22; H, 5.01; B, 1.50; N, 5.83; O, 4.44. The ESI-MS (m/z) (M+) was obtained by liquid chromatography-mass spectrometry: the theoretical value was 721.29, and the measured value was 721.40.

The synthetic route for a compound

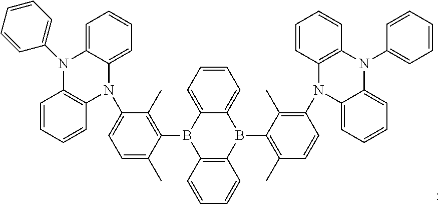 [SMILES: Cc1ccc(N2c3ccccc3N(c3ccccc3)c3ccccc32)c(C)c1B1c2ccccc2B(c2c(C)ccc(N3c4ccccc4N(c4ccccc4)c4ccccc43)c2C)c2ccccc21]

Step 1,

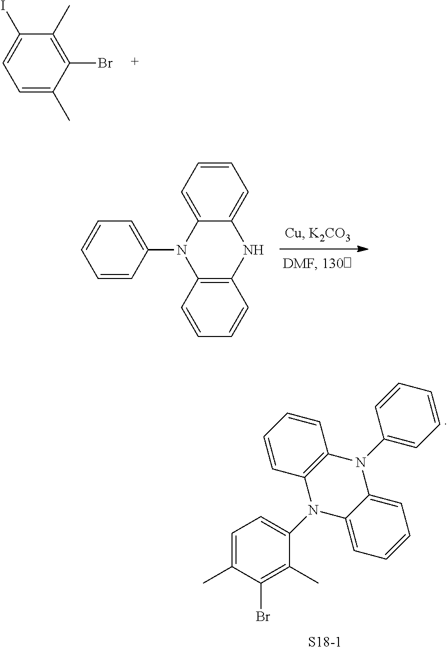

2-bromo-6-iodo-1,3-dimethylbenzene (10 mmol), 5-phenyl-5,10-phenazine (10 mmol), Cu (20 mmol), K₂CO₃ (20 mmol) and N,N-dimethylformamide (20 ml) were mixed under a nitrogen atmosphere to form a solution. The above mixed solution was vacuumed three times with nitrogen gas, and heated and stirred at 130° C. for 24 h. The reaction mixture was filtered with diatomite and washed with dichloromethane (20 ml). The solvent was evaporated under reduced pressure and the resultant was purified by column chromatography (hexane/dichloromethane: 10:1), and then a white solid 5-phenyl-10-(3-bromo-2,4-dimethylphenyl)-5,10-phenazine S18-1 was obtained.

Step 2,

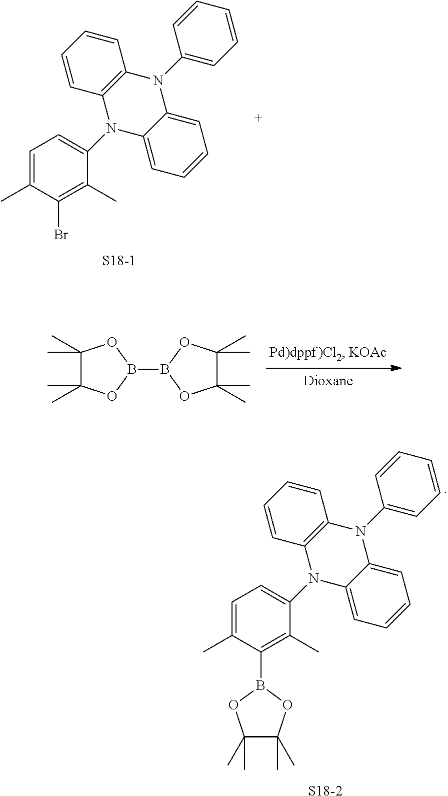

The product of the previous step 5-phenyl-10-(3-bromo-2,4-dimethylphenyl)-5,10-phenazine S18-1 (10 mmol), bis(pinacolato)diboron (20 mmol), (1,1′-bis(diphenylphosphino)ferrocene)palladium(II)dichloride (0.3 mmol) and potassium acetate (45 mmol) were separately added into a 250 ml three-necked flask, and the mixture was vacuumed three times with nitrogen gas, and 100 mL of tetrahydrofuran was added by a syringe. The mixture was stirred at a certain speed, and the resulting mixed solution reactant was heated with reflux at a reaction temperature of 80° C. for 5 h. After the reaction was completed, the mixture was cooled to room temperature and 100 ml of water was added. Then the mixture was extracted with ethyl ether and the obtained organic phase was dried with anhydrous sodium sulfate. The solvent was distilled off and the resultant was purified by column chromatography, and then a product 5-phenyl-10-(3-borate-2,4-dimethylphenyl)-5,10-phenazine S18-2 was obtained.

Step 3,

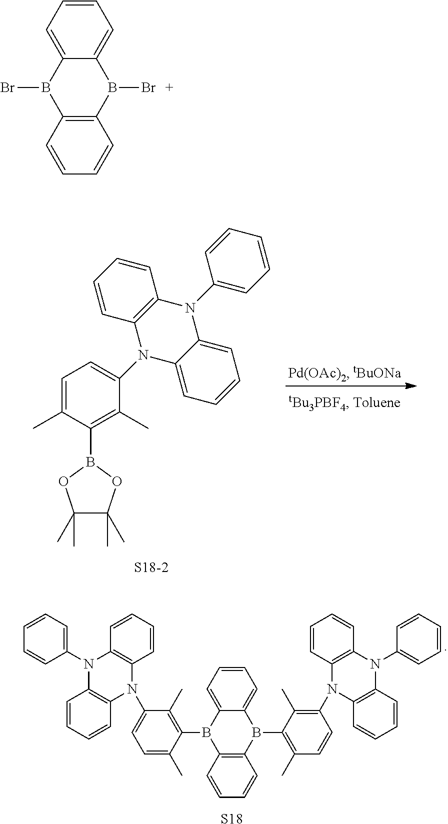 [SMILES: BrB1c2ccccc2B(Br)c2ccccc21 ; Cc1ccc(N2c3ccccc3N(c3ccccc3)c3ccccc32)c(C)c1B1OC(C)(C)C(C)(C)O1 ; "S18-2" ; Cc1ccc(N2c3ccccc3N(c3ccccc3)c3ccccc32)c(C)c1B1c2ccccc2B(c2c(C)ccc(N3c4ccccc4N(c4ccccc4)c4ccccc43)c2C)c2ccccc21 ; "S18"]

In a 250 ml three-necked flask under a nitrogen atmosphere, the product of the previous step S18-2 (20 mmol), 9,10-dibromo-9,10-diboroanthracene (10 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on a silica gel column to give a final product S18.

Elemental analysis for the structure of the S18 compound (molecular formula C₆₄H₅₀B₂N₄): Theoretical value: C, 85.72; H, 5.62; B, 2.41; N, 6.25. Measured Value: C, 85.72; H, 5.64; B, 2.41; N, 6.23. The ESI-MS (m/z) (M+) was obtained by liquid chromatography-mass spectrometry: the theoretical value was 896.42, and the measured value was 896.61.

The synthetic route for a compound

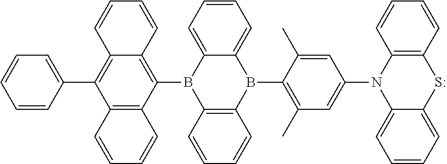

Step 1,

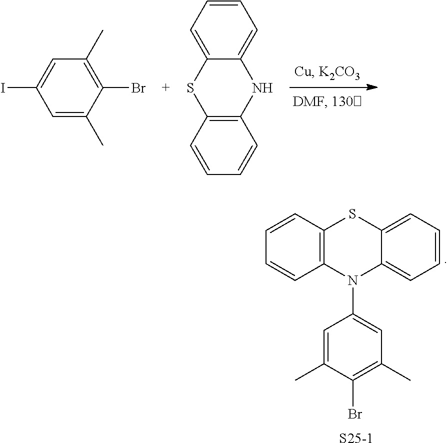

2-bromo-4-iodo-1,3-dimethylbenzene (10 mmol), 5,10-phenothiazine (10 mmol), Cu (20 mmol), K₂CO₃ (20 mmol) and N,N-dimethylformamide (20 ml) were mixed under a nitrogen atmosphere to form a solution. The above mixed solution was vacuumed three times with nitrogen gas, and heated and stirred at 130° C. for 24 h. The reaction mixture was filtered with diatomite and washed with dichloromethane (20 ml). The solvent was evaporated under reduced pressure and the resultant was purified by column chromatography (hexane/dichloromethane: 10:1), and a product 10-(4-bromo-3,5-dimethylphenyl)-phenothiazine S25-1 was obtained.

Step 2,

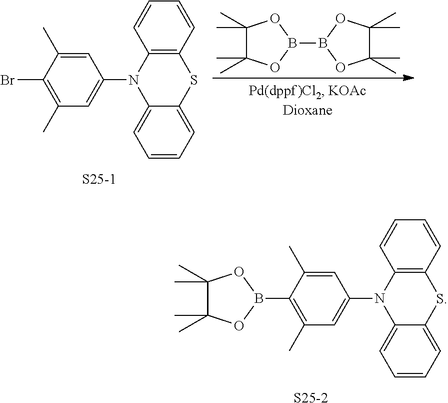

The product of the previous step S25-1 (10 mmol), bis(pinacolato)diboron (20 mmol), (1,1′-bis(diphenylphosphino)ferrocene)palladium(II)dichloride (0.3 mmol) and potassium acetate (45 mmol) were separately added into a 250 ml three-necked flask, and the mixture was vacuumed three times with nitrogen gas, and 100 mL of tetrahydrofuran was added by a syringe. The mixture was stirred at a certain speed, and the resulting mixed solution reactant was heated with reflux at a reaction temperature of 80° C. for 5 h. After the reaction was completed, the mixture was cooled to room temperature and 100 ml of water was added. Then the mixture was extracted with ethyl ether and the obtained organic phase was dried with anhydrous sodium sulfate. The solvent was distilled off and the resultant was purified by column chromatography, and then a product 10-(4-borate-3,5-dimethylphenyl)-phenothiazine S25-2 was obtained.

Step 3,

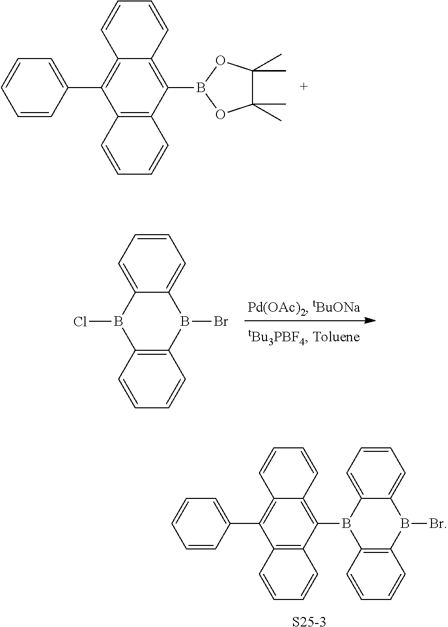 [SMILES: CC1(C)OB(c2c3ccccc3c(-c3ccccc3)c3ccccc23)OC1(C)C ; ClB1c2ccccc2B(Br)c2ccccc21 ; "S25-3" ; BrB1c2ccccc2B(c2c3ccccc3c(-c3ccccc3)c3ccccc23)c2ccccc21]

In a 250 ml three-necked flask under a nitrogen atmosphere, 5-phenyl-10-borate-anthracene (10 mmol), 5-chloro-10-bromo-5,10-diboroanthracene (10 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on a silica gel column to give a brominated intermediate product S25-3.

Step 4,

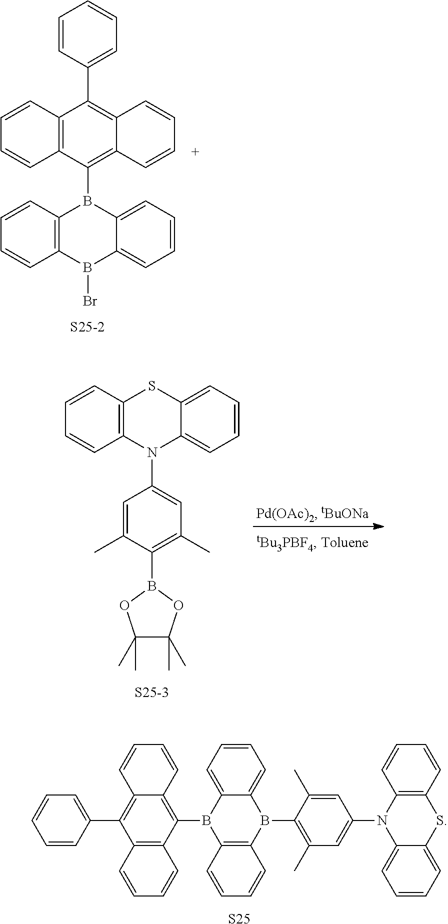 [SMILES: BrB1c2ccccc2B(c2c3ccccc3c(-c3ccccc3)c3ccccc23)c2ccccc21 ; "S25-2" ; "S25-3" ; Cc1cc(N2c3ccccc3Sc3ccccc32)cc(C)c1B1c2ccccc2B(c2c3ccccc3c(-c3ccccc3)c3ccccc23)c2ccccc21 ; Cc1cc(N2c3ccccc3Sc3ccccc32)cc(C)c1B1OC(C)(C)C(C)(C)O1 ; "S25"]

In a 250 ml three-necked flask under a nitrogen atmosphere, S25-2 (10 mmol) and S25-3 10-(4-borate-3,5-dimethylphenyl)-phenothiazine (10 mmol), palladium acetate (0.0006 mol), sodium t-butoxide tBuONa (0.35 mol) and tBuPBF₄ (2 mmol) were successively added to 50 ml of toluene, stirred and mixed, and the mixture was refluxed and reacted at 110° C. for 16 h. The resultant was naturally cooled to room temperature, and 100 ml of water was added thereto, and then the mixture was extracted with dichloromethane and washed with saturated salt solution. After drying the organic layer with anhydrous sodium sulfate, the solvent was distilled off, and the obtained residue was further separated and purified on a silica gel column to give a final product S25.

Elemental analysis for the structure of the S25 compound (molecular formula C₅₂H₃₇B₂NS): Theoretical value: C, 85.61; H, 5.11; B, 2.96; N, 1.92; S, 4.40. Measured Value: C, 85.61; H, 5.12; B, 2.96; N, 1.93; S, 4.38. The ESI-MS (m/z) (M+) was obtained by liquid chromatography-mass spectrometry: the theoretical value was 729.28, and the measured value was 729.35.

In the following, the invention will be explained in detail by the following examples in order to give a better understanding of the various aspects of the invention and its advantages. However, it should be understood that the following examples are non-limiting and are merely illustrative of certain embodiments of the invention.

### Example 1

This example provides an organic light emitting device N1. As shown in FIG. 2, the organic light emitting device includes: a substrate 1, an ITO anode 2, a first hole transporting layer 3, a second hole transporting layer 4, a light emitting layer 5, a first electron transporting layer 6, a second electron transporting layer 7, a cathode 8 (magnesium-silver electrode with a mass ratio of magnesium to silver of 9:1) and a capping layer (CPL) 9; wherein the thickness of the ITO anode 2 is 15 nm, the thickness of the first hole transporting layer 3 is 10 nm, the thickness of the second hole transporting layer 4 is 110 nm, the thickness of the light emitting layer 5 is 30 nm, the thickness of the first electron transporting layer 6 is 30 nm, the thickness of the second electron transporting layer 7 is 5 nm, the thickness of the magnesium-silver electrode 8 is 15 nm, and the thickness of the capping layer (CPL) 9 is 100 nm.

The steps for preparing the organic light emitting device N1 are as follows:

1) A glass substrate was cut into a size of 50 mm×50 mm×0.7 mm, sonicated in isopropanol and deionized water for 30 minutes respectively, and then exposed to ozone for about 10 minutes for cleaning; the obtained glass substrate with ITO anode was mounted on a vacuum deposition apparatus;

2) Hole injection layer material HAT-CN was deposited on the ITO anode layer 2 by a vacuum evaporation method at a vacuum degree of 2×10⁻⁶ Pa to a thickness of 10 nm, and the obtained layer was the first hole transporting layer 3;

3) The material of the second hole transporting layer 4 TAPC was deposited on the first hole transporting layer 3 by a vacuum evaporation to a thickness of 110 nm, and the obtained layer was the second hole transporting layer 4.

4) The light emitting layer 5 was co-deposited on the hole transporting layer 4, wherein the compound S2

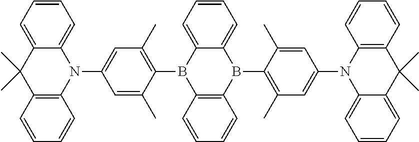

designed in the present disclosure was used as a dopant material for the light emitting layer, 3,3′-bis(N-carbazolyl)-1,1′-biphenyl (mCBP) was used as a host material for the light emitting layer, the mass ratio of the compound S2 to mCBP was 1:9, and the thickness of the light emitting layer 5 was 30 nm;

5) The first electron transporting layer 6 was vacuum-deposited on the light emitting layer 5, wherein the material of the first electron transporting layer 6 was TPBi, and the thickness thereof was 30 nm;

6) The second electron transporting layer 7 was vacuum-deposited on the first electron transporting layer 6, wherein the material of the second electron transporting layer 7 was Alq3, the thickness thereof was 5 nm;

7) The magnesium-silver electrode was vacuum-deposited on the second electron transporting layer 7, wherein the mass ratio of Mg to Ag was 9:1, and the magnesium-silver electrode had a thickness of 15 nm and was used as the cathode 8; and

8) The material CBP was vacuum-deposited on the cathode 8 to a thickness of 100 nm, and the obtained layer was used as a cathode covering layer (capping layer).

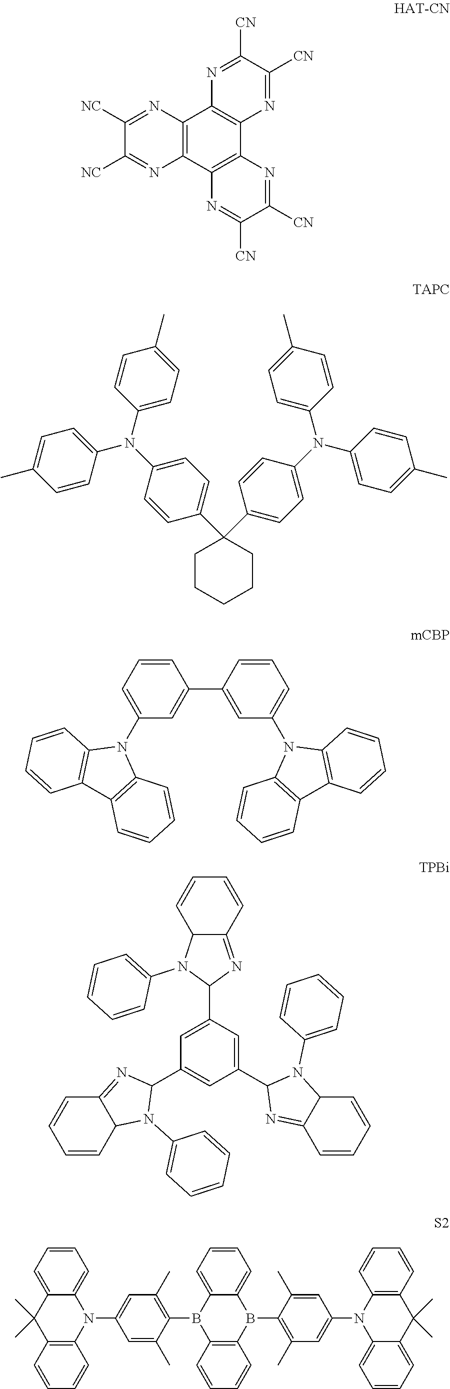

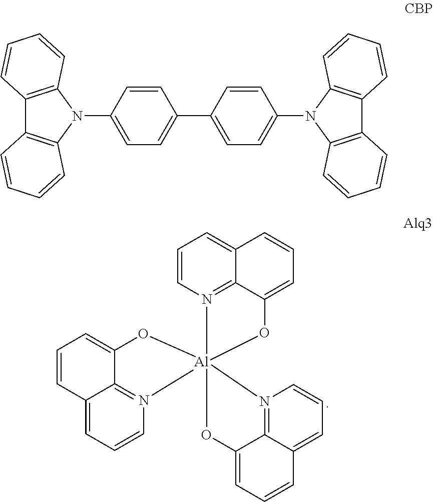

### Example 2

The difference of the present example from Example 1 is that an organic light emitting device N2 is provided wherein the compound S2 is replaced with the compound S5

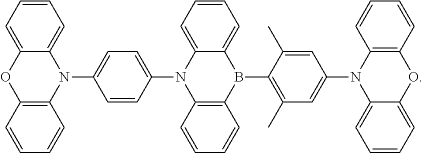 [SMILES: Cc1cc(N2c3ccccc3Oc3ccccc32)cc(C)c1B1c2ccccc2N(c2ccc(N3c4ccccc4Oc4ccccc43)cc2)c2ccccc21]

### Example 3

The difference of the present example from Example 1 is that an organic light emitting device N3 is provided wherein the compound S2 is replaced with the compound S18

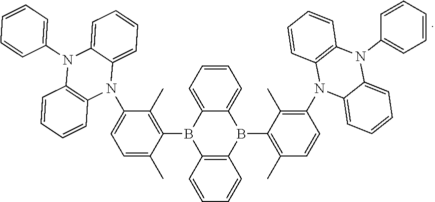 [SMILES: Cc1ccc(N2c3ccccc3N(c3ccccc3)c3ccccc32)c(C)c1B1c2ccccc2B(c2c(C)ccc(N3c4ccccc4N(c4ccccc4)c4ccccc43)c2C)c2ccccc21]

### Example 4

The difference of the present example from Example 1 is that an organic light emitting device N4 is provided wherein the compound S2 is replaced with the compound S23

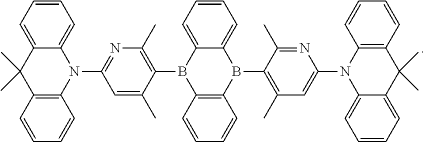

### Example 5

The difference of the present example from Example 1 is that an organic light emitting device N5 is provided wherein the compound S2 is replaced with the compound S25

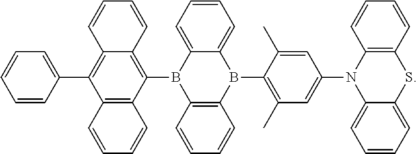 [SMILES: Cc1cc(N2c3ccccc3Sc3ccccc32)cc(C)c1B1c2ccccc2B(c2c3ccccc3c(-c3ccccc3)c3ccccc23)c2ccccc21]

### Example 6

The difference of the present example from Example 1 is that an organic light emitting device N6 is provided wherein the compound S2 is replaced with the compound S31

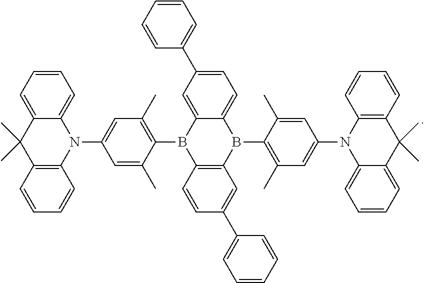

### Comparative Example 1

The difference of the present example from Example 1 is that an organic light emitting device C1 is provided wherein the compound S2 is replaced with a compound D1

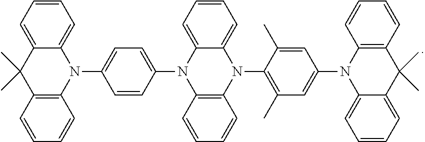

### Comparative Example 2

The difference of the present example from Example 1 is that an organic light emitting device C2 is provided wherein the compound S2 is replaced with a compound D2

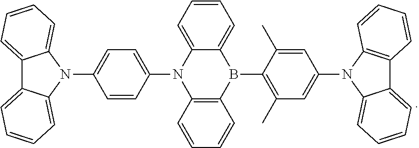 [SMILES: Cc1cc(-n2c3ccccc3c3ccccc32)cc(C)c1B1c2ccccc2N(c2ccc(-n3c4ccccc4c4ccccc43)cc2)c2ccccc21]

Performance Testing:

(1) Simulation Calculation of Compounds:

The energy level difference between singlet state and triplet state of organic materials can be obtained by Guassian 09 software (Guassian Inc.). For specific simulation method of energy level difference ΔE_{ST}, please refer to J. Chem. Theory Comput., 2013, DOI: 10.1021/ct400415r. Molecular structure optimization and excitation can be accomplished by the TD-DFT method “B3LYP” and the basis set “6-31g(d)”. The present disclosure is directed to the compounds S2, S5, S18, S23, S25, S31 and D1 and D2, and the results are shown in Table 1.

(2) Performance Evaluation of Organic Photoelectric Devices

The present disclosure relates to compounds S2, S5, S18, S23, S25, S31 and D1 and D2 in Table 1, which are respectively made into devices, corresponding to the device numbers N1-N6 and C1 and C2. The electric currents at different voltages of these organic photoelectric devices prepared in examples and comparative examples were tested by a Keithley 2365A digital nanovoltmeter, and then current densities at different voltages of these organic photoelectric devices were obtained through dividing the current by the light emitting area. The brightnesses and radiant energy flow densities at different voltages of the organic photovoltaic devices prepared according to examples and comparative examples were measured using a Konicaminolta CS-2000 spectroradiometer. Based on the current densities and brightnesses of the organic photoelectric device at different voltages, the current efficiency (Cd/A) and the external quantum efficiency EQE at the same current density (10 mA/cm²) were obtained, and the results are shown in Table 2.

TABLE 1
Results of simulation calculation of compounds

| | | HOMO | LUMO | S₁ | T₁ | ΔE_{ST} |
|---|---|---|---|---|---|---|
| | Compounds | (ev) | (ev) | (ev) | (ev) | (ev) |
| Example 1 | S2 | −5.27 | −2.46 | 2.60 | 2.65 | 0.05 |
| Example 2 | S5 | −5.45 | −2.84 | 2.78 | 2.74 | 0.04 |
| Example 3 | S18 | −5.51 | −2.75 | 2.83 | 2.69 | 0.14 |
| Example 4 | S23 | −5.57 | −2.62 | 2.72 | 2.64 | 0.08 |
| Example 5 | S25 | −5.43 | −2.66 | 2.89 | 2.76 | 0.13 |
| Example 6 | S31 | −5.40 | −2.58 | 2.70 | 2.58 | 0.12 |
| Comparative | D1 | −5.62 | −2.81 | 2.65 | 2.28 | 0.37 |
| Example 1 | | | | | | |
| Comparative | D2 | −5.59 | −2.74 | 2.88 | 2.49 | 0.39 |
| Example 2 | | | | | | |

It can be seen from Table 1 that the ΔE_{ST} of all the compounds in the examples of the present disclosure is less than 0.15 ev, which realizes a smaller energy level difference between singlet state and triplet state and thereby facilitates reverse intersystem crossing. In addition, the fluorescence lifetime of all the compounds is on the order of microseconds with significant delayed fluorescence effects. The thermally activated delayed fluorescence material provided by the present disclosure has a better potential compared to comparative examples 1 and 2 in which the compounds have larger energy level difference ΔE_{ST}.

TABLE 2
Results of performance evaluation of organic photoelectric devices

| Devices | Vₒₙ[V] | CE_{(10 mA/cm}²₎ (cdA⁻¹) | EQE₍ₘₐₓ₎ (%) |
|---|---|---|---|
| N1 | 3.81 | 27.3 | 17.8 |
| N2 | 3.82 | 28.6 | 18.2 |
| N3 | 3.80 | 30.1 | 18.9 |
| N4 | 3.82 | 26.9 | 16.8 |
| N5 | 3.81 | 31.7 | 19.1 |
| N6 | 3.80 | 29.5 | 18.4 |
| C1 | 4.02 | 20.3 | 13.4 |
| C2 | 3.95 | 22.6 | 15.0 |

As can be seen from Table 2, the maximum external quantum efficiencies of the N1-N6 devices comprising the thermally activated delayed fluorescence material provided by the present disclosure are 16.8%-19.1%, and the maximum reaches 19.1%, which is increased by about 42% relative to the EQE₍ₘₐₓ₎ of the comparative device C1 and about 28% relative to the EQE₍ₘₐₓ₎ of the comparative device C2. This is mainly due to the fact that the thermally activated delayed fluorescence material provided by the present disclosure has a higher triplet energy and a smaller energy level difference ΔE_{ST}. The material designed by the present disclosure is applied in the evaporation process, the efficiency is obviously improved, the voltage reduction effect is obvious, and the power consumption of the device is effectively reduced.

What is claimed is:

1. A thermally activated delayed material being a compound having the structure of formula (I): 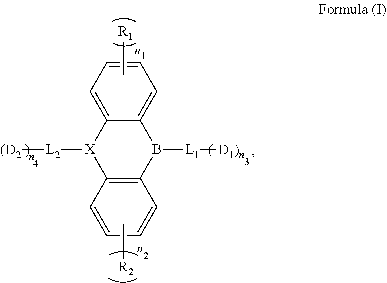
in formula (I), X is a boron atom or a nitrogen atom;
in formula (I), D₁ and D₂ are each independently any one selected from the following groups: 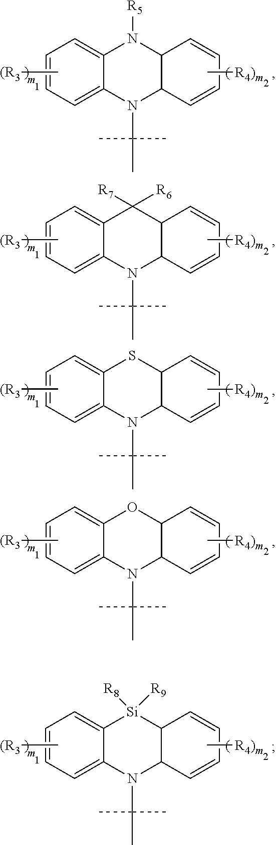
wherein R₃, R₄, R₅, R₆, R₇, R₈ and R₉ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl;
m₁ and m₂ are each independently an integer of 0-4; and in the same group, the sum of m₁ and m₂ is less than or equal to 4;
in formula (I), R₁ and R₂ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl;
in formula (I), n₁ and n₂ are each independently an integer of 0-4, and the sum of n₁ and n₂ is less than or equal to 4;
in formula (I), n₃ and n₄ are each independently an integer greater than or equal to 0;
in formula (I), L₁ and L₂ are each independently any one selected from substituted or unsubstituted aromatic groups; and the number of the substituents on the aromatic group in L₁ and L₂ is represented by m₃.

2. The thermally activated delayed material of claim 1, wherein the sum of n₁, n₂, m₁, m₂ and m₃ is less than or equal to 4.

3. The thermally activated delayed material of claim 1, wherein the sum of n₁, n₂, m₁ and m₂ is 0 or 1.

4. The thermally activated delayed material of claim 1, wherein m₁=0 or m₂=0, or R₁, R₂, R₃ or R₄ are each independently any one selected from the group consisting of methyl, ethyl, phenyl and tolyl.

5. The thermally activated delayed material of claim 1, wherein R₅, R₆, R₇, R₈ and R₉ are each independently any one selected from the group consisting of methyl, ethyl, phenyl and tolyl.

6. The thermally activated delayed material of claim 1, wherein in formula (I), L₁ group is located on para position or meta position.

7. The thermally activated delayed material of claim 1, wherein in formula (I), D₁-L₁- group is the same as D₂-L₂- group.

8. The thermally activated delayed material of claim 1, wherein in formula (I), both n₁ and n₂ are 0, and D₁-L₁- group and D₂-L₂- group are the same.

9. The thermally activated delayed material of claim 1, wherein L₁ and L₂ are each independently selected from any one of the following groups, or any one of the following groups substituted with a substituent:

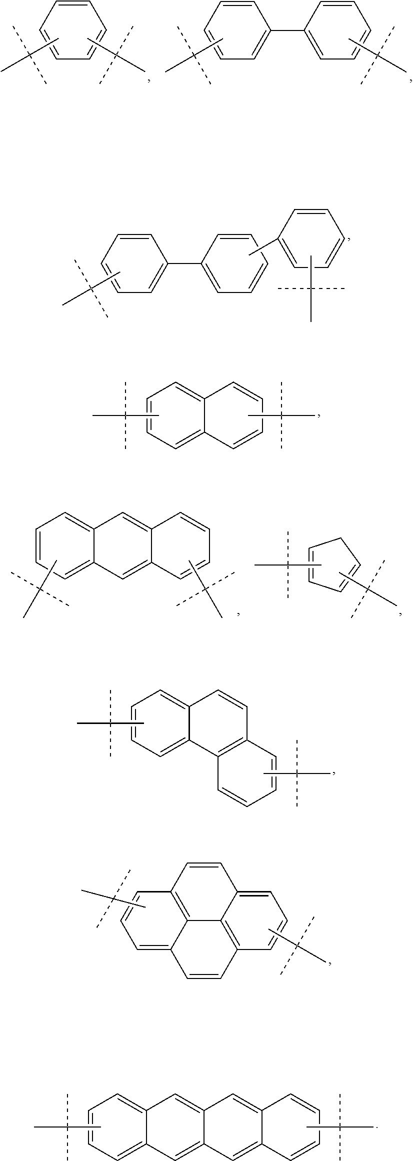

10. The thermally activated delayed material of claim 1, wherein L₁ and L₂ are each independently selected from any one of the following groups, or any one of the following groups substituted with a substituent:

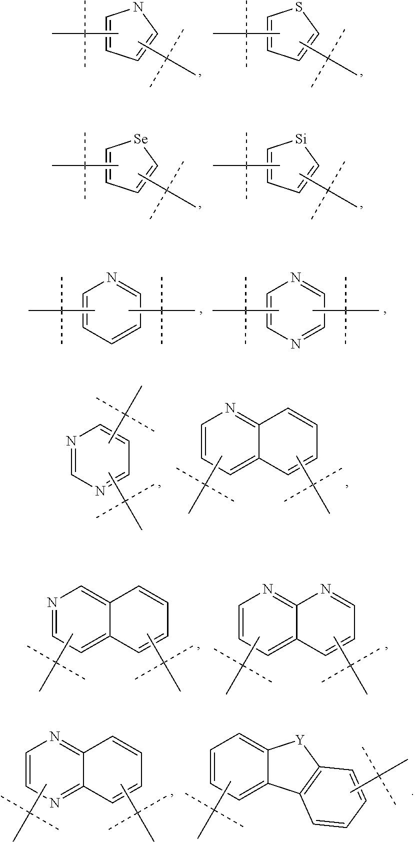

11. The thermally activated delayed material of claim 1, wherein the energy level difference between the lowest singlet state S₁ and the lowest triplet state T₁ of the thermally activated delayed material ΔE_{ST} is less than or equal to 0.30 eV.

12. The thermally activated delayed material of claim 1, wherein the thermally activated delayed material comprises any one selected from the group consisting of the following compounds, and a combination of at least two thereof:

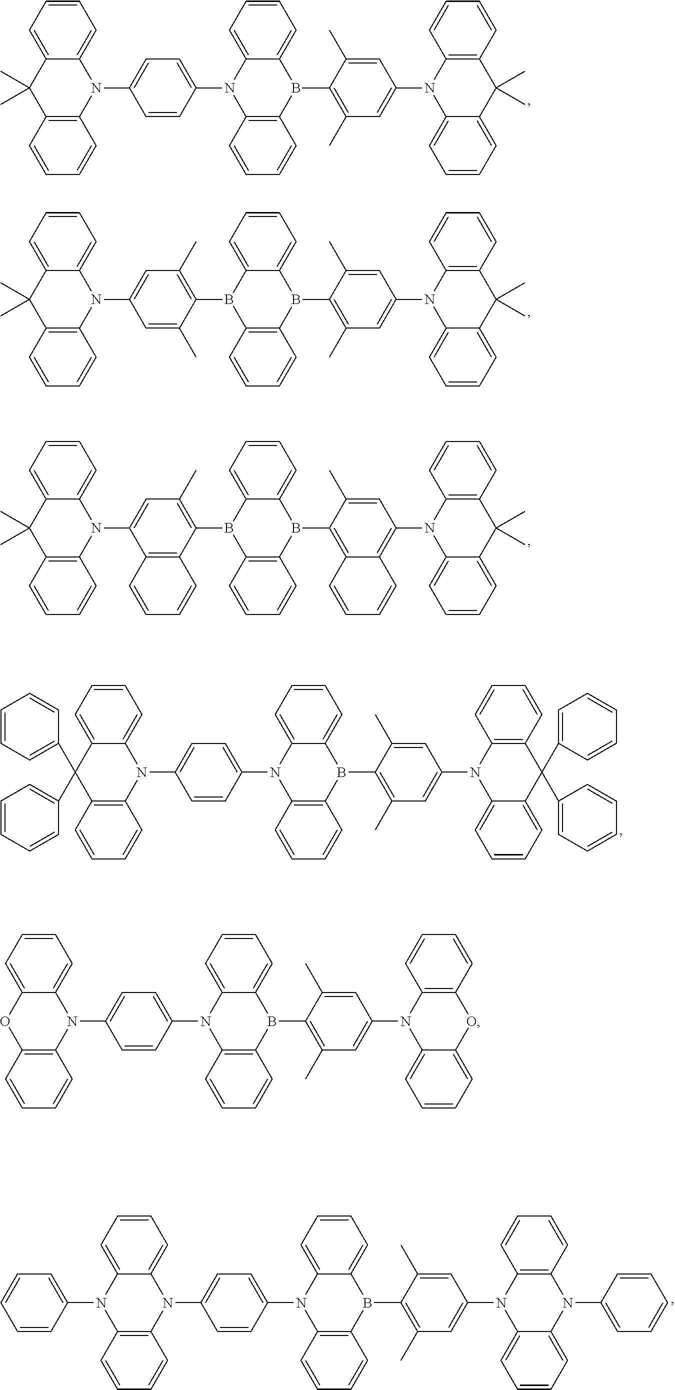

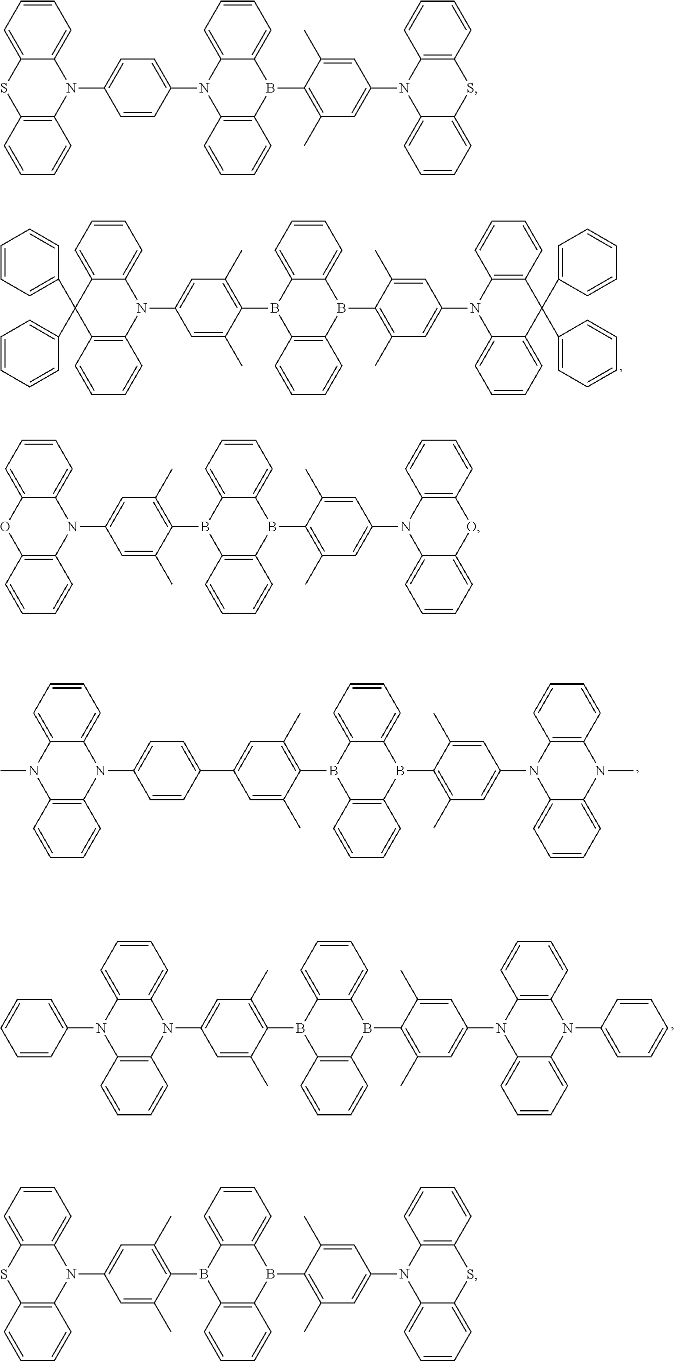

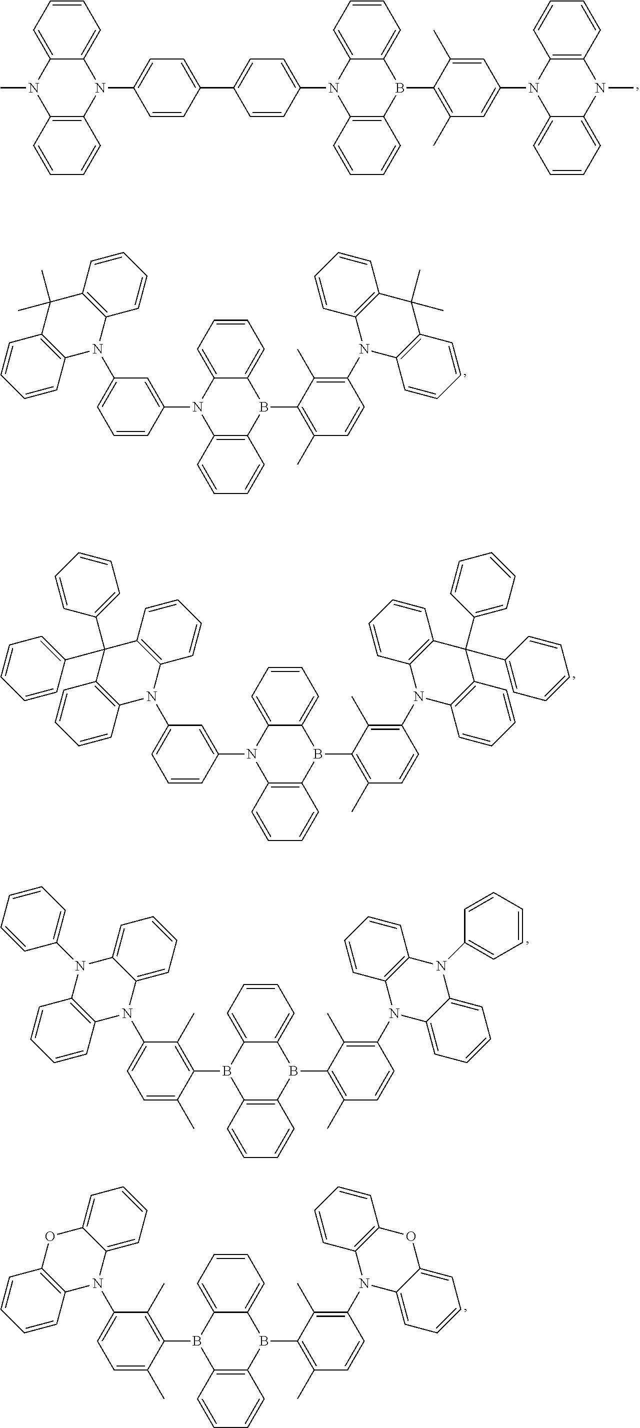

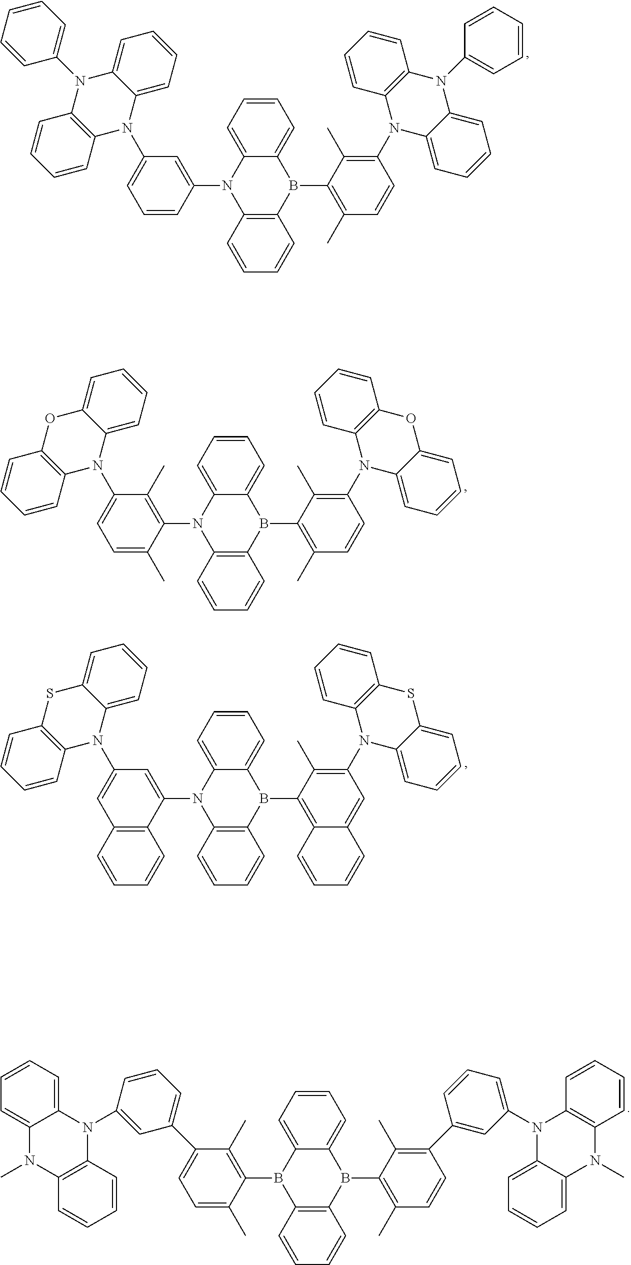 [SMILES: Cc1ccc(N2c3ccccc3N(c3ccccc3)c3ccccc32)c(C)c1B1c2ccccc2N(c2cccc(N3c4ccccc4N(c4ccccc4)c4ccccc43)c2)c2ccccc21 ; Cc1ccc(N2c3ccccc3Oc3ccccc32)c(C)c1B1c2ccccc2N(c2c(C)ccc(N3c4ccccc4Oc4ccccc43)c2C)c2ccccc21 ; Cc1c(N2c3ccccc3Sc3ccccc32)cc2ccccc2c1B1c2ccccc2N(c2cc(N3c4ccccc4Sc4ccccc43)cc3ccccc23)c2ccccc21 ; Cc1ccc(-c2cccc(N3c4ccccc4N(C)c4ccccc43)c2)c(C)c1B1c2ccccc2B(c2c(C)ccc(-c3cccc(N4c5ccccc5N(C)c5ccccc54)c3)c2C)c2ccccc21]

13. The thermally activated delayed material of claim 1, wherein the thermally activated delayed material comprises any one selected from the group consisting of the following compounds, and a combination of at least two thereof:

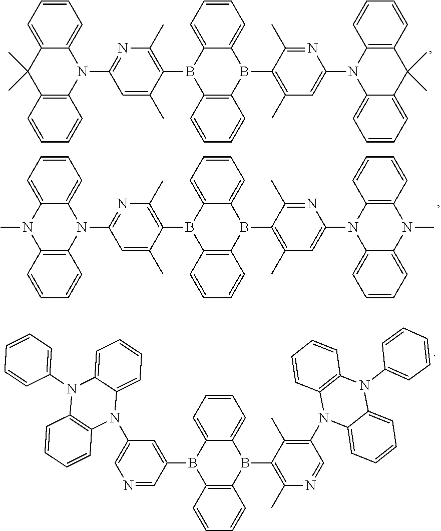

14. The thermally activated delayed material of claim 1, wherein the thermally activated delayed material comprises any one selected from the group consisting of the following compounds, and a combination of at least two thereof:

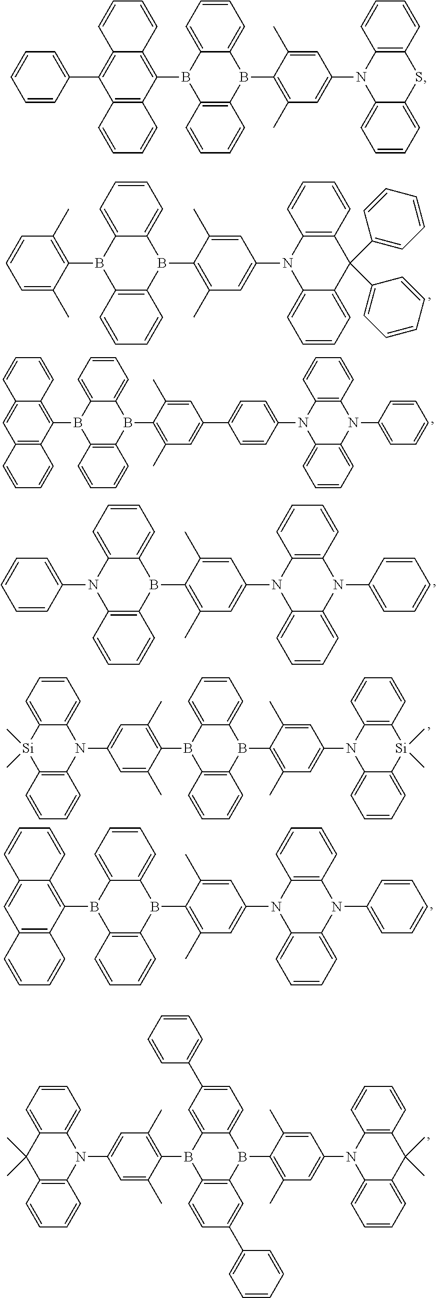

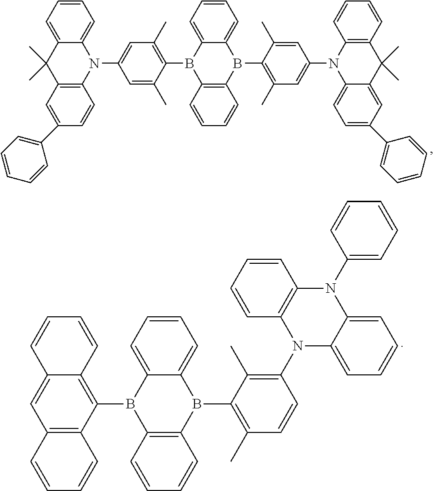

15. An organic photoelectric device comprising an anode, a cathode, and at least one organic thin film layer between the anode and the cathode; the organic thin film layer comprises a light emitting layer, and any one selected from the group consisting of a hole transporting layer, a hole injection layer, an electron blocking layer, a hole blocking layer, an electron transporting layer, an electron injection layer, and a combination of at least two thereof;
the light emitting layer comprises any one or a combination of at least two of the following thermally activated delayed materials being a compound having the structure of formula (I): 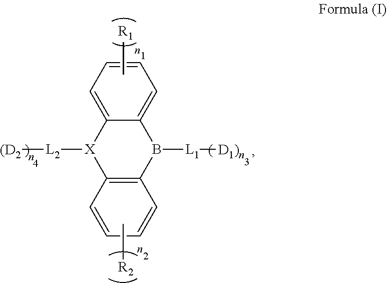
in formula (I), X is a boron atom or a nitrogen atom;
in formula (I), D₁ and D₂ are each independently any one selected from the following groups: 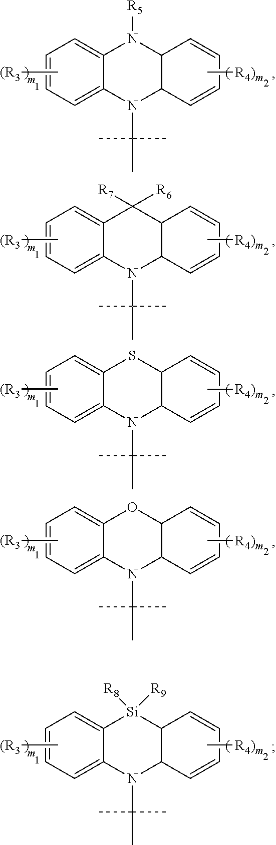
wherein R₃, R₄, R₅, R₆, R₇, R₈ and R₉ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl;
m₁ and m₂ are each independently an integer of 0-4; and in the same group, the sum of m₁ and m₂ is less than or equal to 4;
in formula (I), R₁ and R₂ are each independently any one selected from the group consisting of substituted or unsubstituted C1-C20 alkyl, substituted or unsubstituted C3-C20 cycloalkyl, substituted or unsubstituted C1-C20 alkoxy, substituted or unsubstituted C3-C20 heterocyclic group, substituted or unsubstituted C6-C40 aryl, and substituted or unsubstituted C5-C40 heteroaryl;
in formula (I), n₁ and n₂ are each independently an integer of 0-4, and the sum of n₁ and n₂ is less than or equal to 4;
in formula (I), n₃ and n₄ are each independently an integer greater than or equal to 0;
in formula (I), L₁ and L₂ are each independently any one selected from substituted or unsubstituted aromatic groups; and the number of the substituents on the aromatic group in L₁ and L₂ is represented by m₃;
and the compound is used as any one of a dopant material, a co-doping material, or a host material.

16. The organic photoelectric device of claim 15, wherein the cathode is covered with a capping layer which has a refractive index of 1.85-2.05.

17. The organic photoelectric device of claim 15, wherein the light emitting layer is made of the thermally activated delayed material according to claim 1 and a host material.

18. The organic photoelectric device of claim 15, wherein the light emitting layer comprises a host material and a guest material; the thermally activated delayed material is used as the guest material for the light emitting layer, and the difference between the HOMO of the host material and the HOMO of the guest material is less than 0.6 eV, or the difference between the LUMO of the host material and the LUMO of the guest material is less than 0.6 eV.

19. The organic photoelectric device of claim 18, wherein the thermally activated delayed material is used as a guest material for the light emitting layer, and the host material is any one selected from the group consisting of 2,8-bis(diphenylphosphinyl)dibenzothiophene, 4,4′-bis(9-carbazole)biphenyl, 3,3′-bis(N-carbazolyl)-1,1′-biphenyl, 2,8-bis(diphenylphosphinoxy)dibenzofuran, bis (4-(9H-carbazolyl-9-yl)phenyl)diphenylsilane, 9-(4-tert-butylphenyl)-3,6-bis(triphenylsilyl)-9h-carbazole, bis(2-diphenylphosphine oxide)diphenylether, 1,3-bis[3,5-di(pyridin-3-yl)phenyl]benzene, 4,6-bis(3,5-di (3-pyridin)ylphenyl)-2-methylpyrimidine, 9-(3-(9H-carbazolyl-9-yl)phenyl)-9H-carbazole-3-cyano, 9-phenyl-9-[4-(triphenylsilyl)phenyl]-9H-fluorene, 1,3,5-tris(1-phenyl-1H-benzimidazol-2-yl)benzene, diphenyl [4-(triphenylsilyl)phenyl]phosphine oxide, 4,4′,4″-tris(carbazol-9-yl)triphenylamine, 2,6-dicarbazole-1,5-pyridine, polyvinylcarbazole, polyfluorene, and a combination of at least two thereof.

20. The organic photoelectric device of claim 15, wherein the light emitting layer comprises the thermally activated delayed material according to claim 1, and the hole injection material, the hole transporting material, and the electron blocking material are each independently any one selected from the group consisting of N,N′-diphenyl-N,N′-(1-naphthyl)-1,1′-biphenyl-4,4′-diamine, 4,4′,4″-tris(carbazol-9-yl)triphenylamine, 1,3-dicarbazol-9-yl benzene, 4,4′-bis(9-carbazole)biphenyl, 3,3′-bis(N-carbazolyl)-1,1′-biphenyl, 2,3,6,7,10,11-hexacyano-1,4,5,8,9,12-hexaazabenzophenanthrene, 4,4′-cyclohexyldi[N,N-di(4-methylphenyl)aniline, N,N′-diphenyl-N,N′-(1-naphthyl)-1,1′-biphenyl-4,4′-diamine, N,N′-bis(naphthalen-2-yl)-N,N′-bis(phenyl)biphenyl-4,4′-diamine, poly(3,4-ethylenedioxythiophene)-polystyrene sulfonic acid, polyvinylcarbazole, 9-phenyl-3,9-bicarbazole, molybdenum trioxide, and a combination of at least two thereof; and the hole blocking material, the electron transporting material, and the electron injection material are each independently any one selected from the group consisting of 2,8-bis(diphenylphosphinyl)dibenzothiophene, TSPO1, TPBi, 2,8-bis(diphenylphosphinoxy)dibenzofuran, bis(2-diphenylphosphine oxide)diphenylether, lithium fluoride, 4,6-bis(3,5-bis(3-pyridin)ylphenyl)-2-methylpyrimidine, 4,7-diphenyl-1,10-phenanthroline, 1,3,5-tris[(3-pyridyl)-3-phenyl]benzene, tris[2,4,6-trimethyl-3-(3-pyridyl)phenyl]borane, 1,3-bis(3,5-dipyridin-3-ylphenyl)benzene, 1,3-bis[3,5-bis(pyridin-3-yl)phenyl]benzene, 2,4,6-tris(biphenyl-3-yl)-1,3,5-triazine, diphenyl bis[4-(pyridin-3-yl)phenyl]silane, cesium carbonate, bis(2-methyl-8-hydroxyquinoline-N1,O8)-(1,1′-biphenyl-4-hydroxy)aluminum, 8-hydroxyquinoline-lithium, tris(8-hydroxyquinoline)aluminum, and a combination of at least two thereof.
